(19) United States
(12) Patent Application Publication
(10) Pub. No.: US 2023/0180451 A1
(43) Pub. Date: Jun. 8, 2023

(54) Semiconductor Structure With Source/Drain Contact Plugs And Method For Forming The Same

(71) Applicant: Taiwan Semiconductor Manufacturing Company, Ltd., Hsin-Chu (TW)

(72) Inventors: Shih-Hao Lin, Hsinchu (TW); Chih-Chuan Yang, Hsinchu (TW)

(21) Appl. No.: 17/876,966

(22) Filed: Jul. 29, 2022

Related U.S. Application Data
(60) Provisional application No. 63/285,828, filed on Dec. 3, 2021.

(51) Int. Cl. H01L 27/11; H01L 29/06; H01L 29/423; H01L 29/08; H01L 29/775; H01L 29/66

(52) U.S. Cl. CPC H01L 27/1108; H01L 29/0673; H01L 29/42392; H01L 29/0847; H01L 29/775; H01L 29/66439

(57) ABSTRACT

A semiconductor structure is provided. The semiconductor structure includes a first set of nanostructures stacked over a substrate and spaced apart from one another, a second set of nanostructures stacked over the substrate and spaced apart from one another, a first source/drain feature adjoining the first set of nanostructures, a second source/drain feature adjoining the second set of nanostructures, a first contact plug landing on and partially embedded in the first source/drain feature, and a second contact plug landing on and partially embedded in the second source/drain feature. A bottom of the first contact plug is lower than a bottom of the second contact plug.

### PRIORITY CLAIM

This application claims the benefit of U.S. Provisional Application No. 63/285,828, filed on Dec. 4, 2021 and entitled “SEMICONDUCTOR DEVICE WITH SOURCE/DRAIN CONTACT AND METHOD FOR FORMING THE SAME,” the entirety of which is incorporated herein by reference.

### BACKGROUND

The electronics industry is experiencing an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., minimum feature size) and thereby improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). One such multi-gate device that has been introduced is the gate-all around transistor (GAA). The GAA device gets its name from the gate structure, which can extend around the channel region and provide access to the channel on two or four sides. GAA devices are compatible with conventional complementary metal-oxide-semiconductor (CMOS) processes, and their structure allows them to be aggressively scaled-down while maintaining gate control and mitigating SCEs. In conventional processes, GAA devices provide a channel in a silicon nanowire. However, integration of fabrication of the GAA features around the nanowire can be challenging. For example, while current methods have been satisfactory in many respects, continued improvements are still needed.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 illustrates a simplified diagram of a static random access memory (SRAM), in accordance with some embodiments of the disclosure.

FIG. 2A illustrates a single-port SRAM cell, in accordance with some embodiments of the disclosure.

FIG. 2B illustrates an alternative illustration of the SRAM cell of FIG. 2A, in accordance with some embodiments of the disclosure.

FIG. 3 illustrates a layout showing a group GP of the SRAM in FIG. 1, in accordance with some embodiments of the disclosure.

FIG. 4 is a perspective view of a semiconductor structure of an SRAM cell, in accordance with some embodiments of the disclosure.

FIGS. 5A-1 through 5O-3 are cross-sectional views illustrating the formation of a semiconductor structure of an SRAM cell at various intermediate stages, in accordance with some embodiments of the disclosure.

FIGS. 6A through 6G are cross-sectional views illustrating the formation of a semiconductor structure of an SRAM cell at various intermediate stages, in accordance with some embodiments of the disclosure.

FIGS. 7A through 7H are cross-sectional views illustrating the formation of a semiconductor structure of an SRAM cell at various intermediate stages, in accordance with some embodiments of the disclosure.

FIGS. 8A and 8B are cross-sectional views illustrating the formation of a semiconductor structure of an SRAM cell at various intermediate stages, in accordance with some embodiments of the disclosure.

FIGS. 9A and 9B are cross-sectional views illustrating the formation of a semiconductor structure of an SRAM cell at various intermediate stages, in accordance with some embodiments of the disclosure.

FIGS. 10A and 10B are a flowchart of a method for forming a semiconductor structure, in accordance with some embodiments of the disclosure.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

Further, when a number or a range of numbers is described with “about,” “approximate,” and the like, the term is intended to encompass numbers that are within a reasonable range including the number described, such as within +/−10% of the number described or other values as understood by person skilled in the art. For example, the term “about 5 nm” encompasses the dimension range from 4.5 nm to 5.5 nm.

As the feature sizes continue to decrease, SRAM devices focus on improving cell performance (e.g., current, operation voltage (Vcc_min), etc.), SRAM margin (e.g., write margin and/or read margin) and/or operation speed. For the operation speed of SRAM, the write margin is more critical than read margin. When SRAM devices includes pull-up transistors (PMOS device) with strong performance and pass-gate transistors/pull-down transistors (NMOS device) with weak performance, the “alpha ratio” of the saturation current (“Idsat”), that is the ratio of PU Idsat to PG Idsat, may increase, which may lead worse cell performance (e.g., increase in operation voltage) and/or poor write margin metric (e.g., lower operation speed).

Embodiments of a semiconductor structure are provided. The aspect of the present disclosure is directed to a semiconductor structure of an SRAM device including nanostructure transistors. The semiconductor structure may include a first contact plug landing on and partially embedded in a first source/drain feature of an n-channel nanostructure, and a second contact plug landing on and partially embedded in a second source/drain feature of a p-channel nanostructure. The bottom of the first contact plug may be located at a lower position than the bottom of the second contact plug. Therefore, the n-channel nanostructure transistor may have relatively strong performance while the p-channel nanostructure transistor may have relatively weak performance, which may enhance cell performance (e.g., decrease in operation voltage) and/or expand write margin metric (e.g., increase in operation speed).

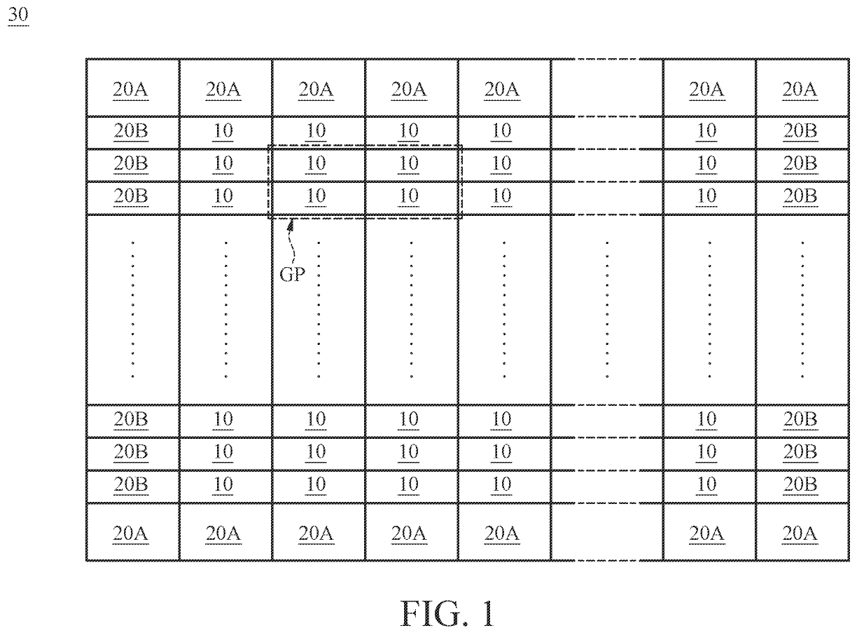

FIG. 1 illustrates a simplified diagram of an SRAM 30, in accordance with some embodiments of the disclosure. The SRAM 30 can be an independent device or be implemented in an IC (e.g. System-on-Chip (SOC)). The SRAM 30 includes a cell array formed by multiple SRAM cells (or called bit cells) 10, and the SRAM cells 10 are arranged in multiple rows and multiple columns in the cell array.

In the fabrication of SRAM cells, the cell array may be surrounded by multiple strap cells 20A and multiple edge cells 20B, and the strap cells 20A and the edge cells 20B are dummy cells for the cell array. In some embodiments, the strap cells 20A are arranged to surround the cell array horizontally, and the edge cells 20B are arranged to surround the cell array vertically. The shapes and sizes of the strap cells 20A and the edge cells 20B are determined according to actual application.

In some embodiments, the shapes and sizes of the strap cells 20A and the edge cells 20B are the same as the SRAM cells 10. In some embodiments, the shapes and sizes of the strap cells 20A, the edge cells 20B and the SRAM cells 10 are different. Moreover, in the SRAM 30, each SRAM cell 10 has the same rectangular shape/region, e.g., the widths and heights of the SRAM cells 10 are the same. The configurations of the SRAM cells 10 are described below.

In the cell array of the SRAM 30, although only one group GP is shown in FIG. 1, the SRAM cells 10 can be divided into multiple groups GP, and each of the groups GP includes four adjacent SRAM cells 10. The groups GP are described in detail below.

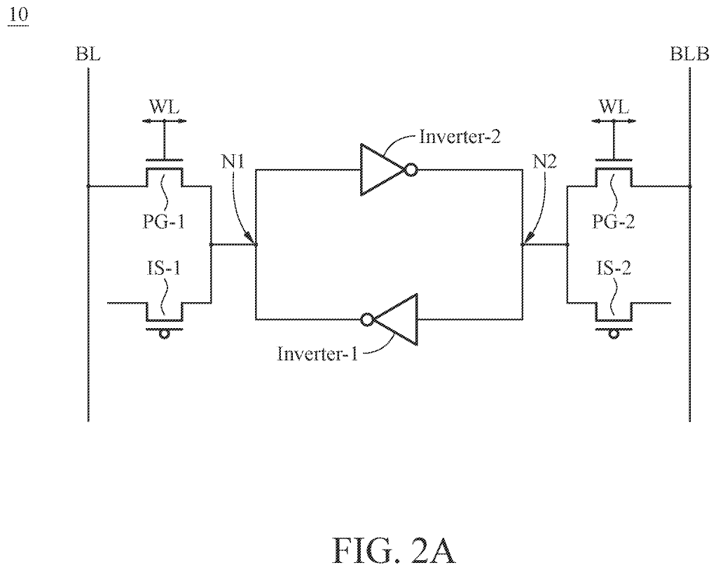

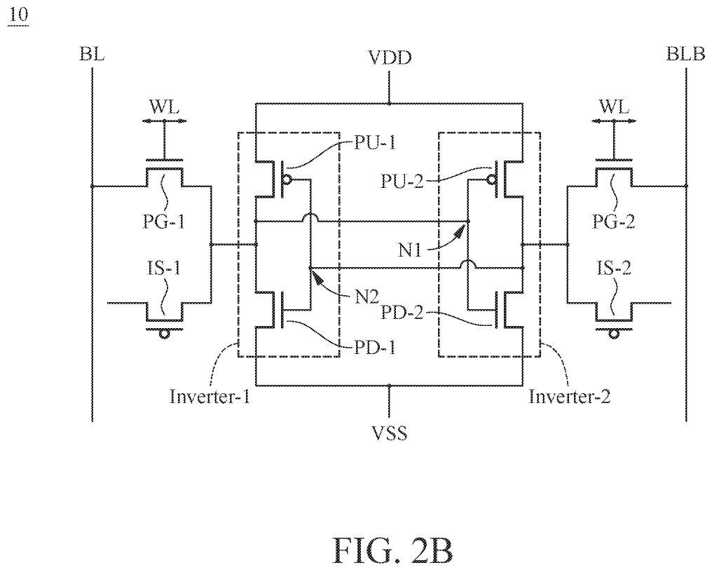

FIG. 2A illustrates a single-port SRAM cell 10, in accordance with some embodiments of the disclosure. The SRAM cell 10 includes a pair of cross-coupled inverters Inverter-1 and Inverter-2, two pass-gate transistors PG-1 and PG-2, and two isolation transistors IS-1 and IS-2. The inverters Inverter-1 and Inverter-2 are cross-coupled between the nodes N1 and N2, and form a latch.

The pass-gate transistor PG-1 is coupled between a bit line BL and the node N1, and the pass-gate transistor PG-2 is coupled between a complementary bit line BLB and the node N2, and the complementary bit line BLB is complementary to the bit line BL. The gates of the pass-gate transistors PG-1 and PG-2 are coupled to the same word-line WL. The isolation transistors IS-1 and IS-2 may have a negligible effect on the operation of the SRAM cell 10, since no current will flow away from the nodes N1 and N2 through the isolation transistors IS-1 or IS-2. Furthermore, the pass-gate transistors PG-1 and PG-2 may be NMOS transistors, and the isolation transistors IS-1 and IS-2 may be PMOS transistors.

FIG. 2B illustrates an alternative illustration of the SRAM cell of FIG. 2A, in accordance with some embodiments of the disclosure. The inverter Inverter-1 in FIG. 2A includes a pull-up transistor PU-1 and a pull-down transistor PD-1, as shown in FIG. 2B. The pull-up transistor PU-1 is a PMOS transistor, and the pull-down transistor PD-1 is an NMOS transistor. The drain of the pull-up transistor PU-1 and the drain of the pull-down transistor PD-1 are coupled to the node N1 connecting the pass-gate transistor PG-1. The gates of the pull-up transistor PU-1 and the pull-down transistor PD-1 are coupled to the node N2 connecting the pass-gate transistor PG-2. Furthermore, the source of the pull-up transistor PU-1 is coupled to a power supply node VDD, and the source of the pull-down transistor PD-1 is coupled to a ground VSS.

Similarly, the inverter Inverter-2 in FIG. 2A includes a pull-up transistor PU-2 and a pull-down transistor PD-2, as shown in FIG. 2B. The pull-up transistor PU-2 is a PMOS transistor, and the pull-down transistor PD-2 is an NMOS transistor. The drains of the pull-up transistor PU-2 and the pull-down transistor PD-2 are coupled to the node N2 connecting the pass-gate transistor PG-2. The gates of the pull-up transistor PU-2 and the pull-down transistor PD-2 are coupled to the node N1 connecting the pass gate transistor PG-1. Furthermore, the source of the pull-up transistor PU-2 is coupled to the power supply node VDD, and the source of the pull-down transistor PD-2 is coupled to the ground VSS.

In some embodiments, the pass-gate transistors PG-1 and PG-2, the isolation transistors IS-1 and IS-2, the pull-up transistors PU-1 and PU-2, and the pull-down transistors PD-1 and PD-2 of the SRAM cell 10 are nanostructure transistors (such as gate-all-around transistors). In some other embodiments, the pass-gate transistors PG-1 and PG-2, the isolation transistors IS-1 and IS-2, the pull-up transistors PU-1 and PU-2, and the pull-down transistors PD-1 and PD-2 of the SRAM cell 10 are fin field effect transistors (FinFETs).

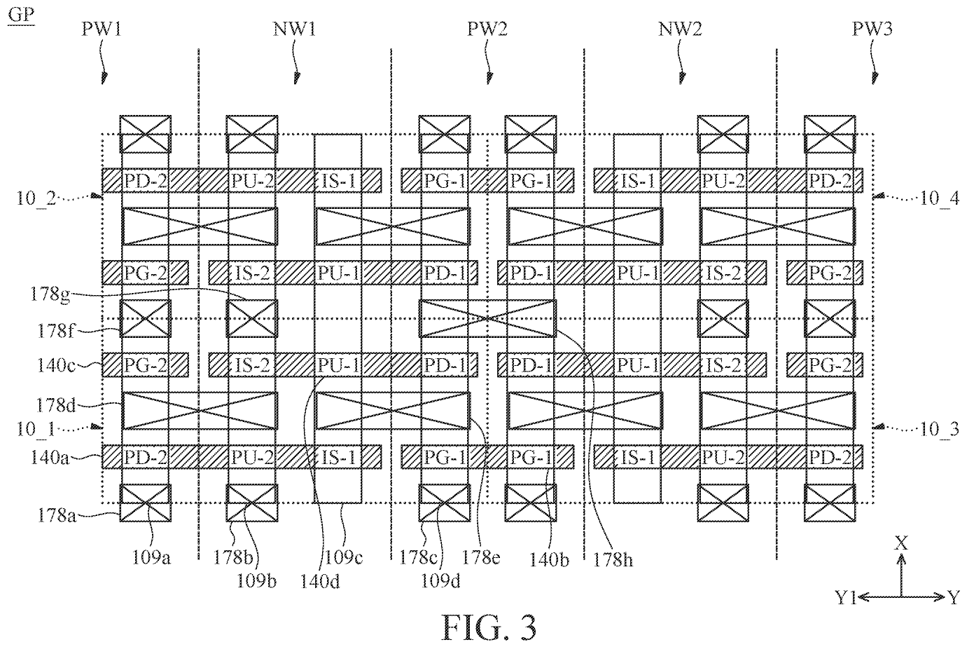

FIG. 3 illustrates a layout showing a group GP of the SRAM 30 in FIG. 1, in accordance with some embodiments of the disclosure. The group GP includes four SRAM cells 10_1, 10_2, 10_3 and 10_4 and is formed by nanostructures 109 and gate stacks 140. As the term is used herein, “a set of nanostructures” refers to active regions of a semiconductor structure that includes multiple semiconductor layers with cylindrical shape, bar shaped and/or sheet shape. Gate stacks 140 extend across and wrap around the nanostructures 109, in accordance with some embodiments.

In some embodiments, the transistors within the SRAM cells 10_1, 10_2, 10_3 and 10_4 are nanostructure transistors in the N-type well regions NW1 and NW2, and in the P-type well regions PW1, PW2 and PW3. The N-type well region NW1 is formed between and adjacent to the P-type well regions PW1 and PW2, and the N-type well region NW2 is formed between and adjacent to the P-type well regions PW2 and PW3.

The two adjacent SRAM cells 10_1 and 10_3 are arranged in the same row of the cell array of the SRAM 30. The two adjacent SRAM cells 10_1 and 10_2 are arranged in the same column of the cell array of the SRAM 30. The two adjacent SRAM cells 10_3 and 10_4 are arranged in the same column of the cell array of the SRAM 30. In other words, the two adjacent SRAM cells 10_2 and 10_4 are arranged in the same row of the cell array of the SRAM 30. In FIG. 3, each of the SRAM cells 10_1, 10_2, 10_3 and 10_4 has the same rectangular shape/region with a width along the Y-direction and a height along the X-direction, and the height is less than the width. It should be noted that the SRAM structure shown in FIG. 3 is merely an example and is not intended to limit the SRAM cells 10 of the SRAM 30.

In the SRAM 30, the nanostructure transistor structures (such as GAA transistor structure) described below may be patterned using any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the nanostructure transistor structure.

In the SRAM cell 10_1, the pass-gate transistor PG-1 is formed at the cross point of the nanostructures 109d and the gate stack 140b on the P-type well region PW2. The pull-down transistor PD-1 is formed at the cross point of the nanostructures 109d and the gate stack 140d on the P-type well region PW2. The pass-gate transistor PG-2 is formed at the cross point of the nanostructures 109a and the gate stack 140c on the P-type well region PW1. The pull-down transistor PD-2 is formed at the cross point of the nanostructures 109a and the gate stack 140a on the P-type well region PW1.

Moreover, in the SRAM cell 10_1, the pull-up transistor PU-1 is formed at the cross point of the nanostructures 109c and the gate stack 140d on the N-type well region NW1. The pull-up transistor PU-2 is formed at the cross point of the nanostructures 109b and the gate stack 140a on the N-type well region NW1. The isolation transistor IS-1 is formed at the cross point of the nanostructures 109c and the gate stack 140a on the N-type well region NW1. The isolation transistor IS-2 is formed at the cross point of the nanostructures 109b and the gate stack 140d on the N-type well region NW1.

Various contact plugs and their corresponding interconnect vias may be employed to electrically connect components in each SRAM cells 10_1 through 10_4. A bit line (BL) (not shown) may be electrically connected to the source of the pass-gate transistor PG-1 through a contact plug 178c, and a complementary bit line (BLB) (not shown) may be electrically connected to the source of the pass-gate transistor PG-2 through a contact plug 178f. Likewise, a contact plug and/or via of a word line (WL) (not shown) may be electrically connected to the gate stack 140b of the pass-gate transistor PG-1, and another contact plug and/or via of the word line (not shown) may be electrically connected to the gate stack 140c of the pass-gate transistor PG-2.

Moreover, a contact plug and/or via of the power supply node VDD (not shown) may be electrically connected to the source of the pull-up transistor PU-1 through a contact plug 178g, and another contact plug and/or via of the power supply node VDD (not shown) may be electrically connected to the source of the pull-up transistor PU-2 through a contact plug 178b. A contact plug and/or via of the ground VSS (not shown) may be electrically connected to the source of the pull-down transistor PD-1 through a contact plug 178h, and another contact plug and/or via of the ground VSS (not shown) may be electrically connected to the source of the pull-down transistor PD-2 through a contact plug 178a.

In addition, a contact plug 178e is configured to electrically connect the drain of the pull-up transistor PU-1 and the drain of the pull-down transistor PD-1, and a contact plug 178d is configured to electrically connect the drain of the pull-up transistor PU-2 and the pull-down transistor PD-2.

As shown in FIG. 3, the Y1-direction is opposite to the Y-direction, and the X-direction is perpendicular to the Y-direction and the Y1-direction. In some embodiments, the gate stack 140a is shared by the pull-down transistor PD-2, the pull-up transistor PU-2 and the isolation transistor IS-1 of the SRAM cell 10_1, the gate stack 140b is shared by the pass-gate transistors PG-1 of the SRAM cells 10_1 and 10_3, the gate stack 140c is shared by the pass-gate transistors PG-2 of the SRAM cell 10_1 and another adjacent SRAM cell (not shown) arranged along the Y1 direction from the SRAM cell 10_1, and the gate stack 140d is shared by the pull-down transistor PD-1, the pull-up transistor PU-1 and the isolation transistor IS-2 of the SRAM cell 10_1.

In some embodiments, the SRAM cell 10_2 is a duplicate cell for the SRAM cell 10_1 but flipped over the Y-axis, the SRAM cell 10_3 is a duplicate cell for the SRAM cell 10_1 but flipped over the X-axis, and the SRAM cell 10_4 is a duplicate cell for the SRAM cell 10_3 but flipped over the Y-axis. The common contact plugs (e.g., the contact plug 178h electrically connected the sources of the pull-down transistors PD-1 in the SRAM cells 10_1 to 10_4 and the ground VSS), are combined to save space.

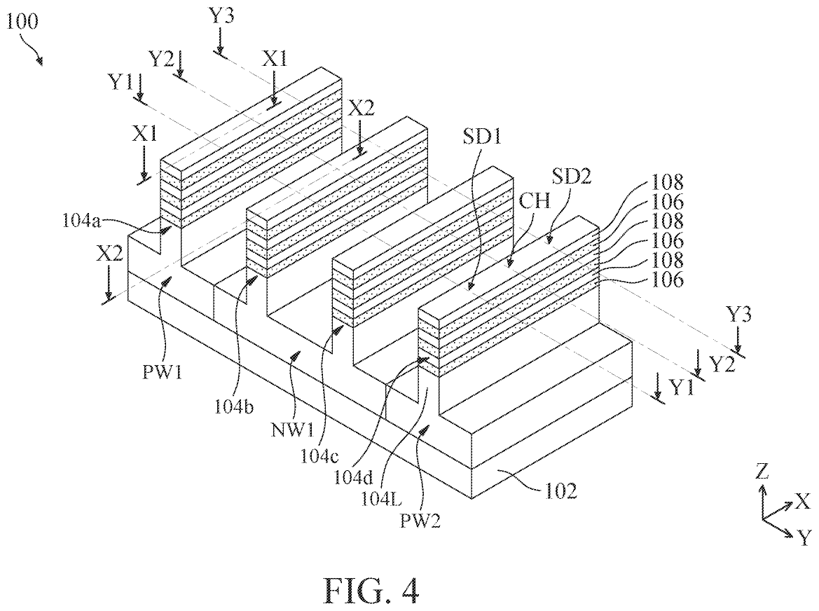

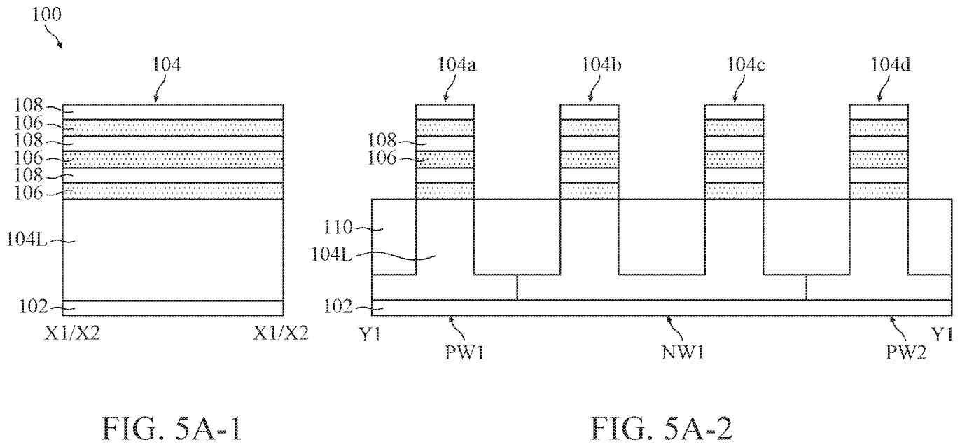

FIG. 4 is a perspective view of a semiconductor structure 100 of an SRAM cell, in accordance with some embodiments of the disclosure. In some embodiments, the semiconductor structure 100 is used to form the SRAM cell 10_1 shown in FIG. 3. The semiconductor structure 100 includes a substrate 102 and fin structures 104 (including 104a-104d) over the substrate 102, in accordance with some embodiments. The fin structure 104a is formed in the P-type well region PW1 of the substrate 102, the fin structures 104b and 104c are formed in the N-type well region NW1 of the substrate 102, and the fin structure 104d is formed in the P-type well region PW2 of the substrate 102, in accordance with some embodiments. In some embodiments, the N-type well region NW1 is formed between and adjacent to the P-type well regions PW1 and PW2. Although four fin structure 104 is illustrated in FIG. 1, the semiconductor structure 100 may include more than four fin structures 104.

For a better understanding of the semiconductor structure 100, the X-Y-Z coordinate reference is provided in the figures of the present disclosure. The X-axis and the Y-axis are generally orientated along the lateral (or horizontal) directions that are parallel to the main surface of the substrate 102. The Y-axis is transverse (e.g., substantially perpendicular) to the X-axis. The Z-axis is generally oriented along the vertical direction that is perpendicular to the main surface of the substrate 102 (or the X-Y plane).

Each of the fin structures 104a-104d includes a lower fin element 104L formed from a portion of the substrate 102 and an upper fin element formed from an epitaxial stack including alternating first semiconductor layers 106 and second semiconductor layer 108, in accordance with some embodiments. The fin structures 104 extend in X direction, in accordance with some embodiments. That is, the fin structures 104a-104d have longitudinal axes parallel to the X direction, in accordance with some embodiments. The X direction may also be referred to as the channel-extending direction. The current of the resulting semiconductor device (i.e., nanostructure transistor) flows in the X direction through the channel.

Each of the fin structures 104a-104d includes a channel region CH and source/drain regions SD1 and SD2, and the channel regions CH are defined between the source/drain regions SD1 and SD2, in accordance with some embodiments. In this disclosure, a source/drain refers to a source and/or a drain. It is noted that in the present disclosure, a source and a drain are interchangeably used and the structures thereof are substantially the same. FIG. 4 shows one channel region CH and two source/drain regions SD1 and SD2 for illustrative purpose and is not intended to be limiting. The number of the channel region and the source/drain regions may be dependent on the cell number, design demand and/or performance consideration of the SRAM. Gate structures or gate stacks (not shown) will be formed with longitudinal axes parallel to the Y direction and extending across and/or surrounds the channel regions CH of the fin structure 104a-104d. The Y direction may also be referred to as a gate-extending direction.

FIG. 4 further illustrates a reference cross-section that is used in later figures. Cross-section X1-X1 is in a plane parallel to the longitudinal axis (X direction) of the fin structure and through the fin structure in the P-type well region (such as the fin structure 104a in P-type well region PW1), in accordance with some embodiments. Cross-section X2-X2 is in a plane parallel to the longitudinal axis (X direction) of the fin structure and through the fin structure in the N-type well region (such as the fin structure 104b in N-type well region NW1), in accordance with some embodiments.

In addition, cross-section Y1-Y1 is in a plane parallel to the longitudinal axis (Y direction) of the gate structure and across the source/drain region SD1 of the fin structures 104a-104d, in accordance with some embodiments. Cross-section Y2-Y2 is in a plane parallel to the longitudinal axis (Y direction) of the gate structure and through the gate structure or gate stack (i.e., across the channel region CH of the fin structures 104a-104d), in accordance with some embodiments. Cross-section Y3-Y3 is in a plane parallel to the longitudinal axis (Y direction) of the gate structure and across the source/drain region SD2 of the fin structures 104a-104d, in accordance with some embodiments.

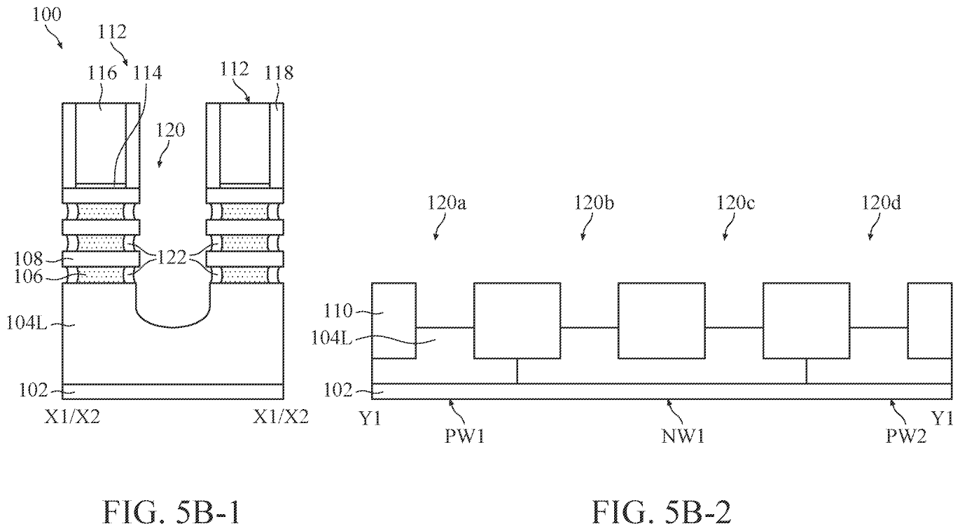

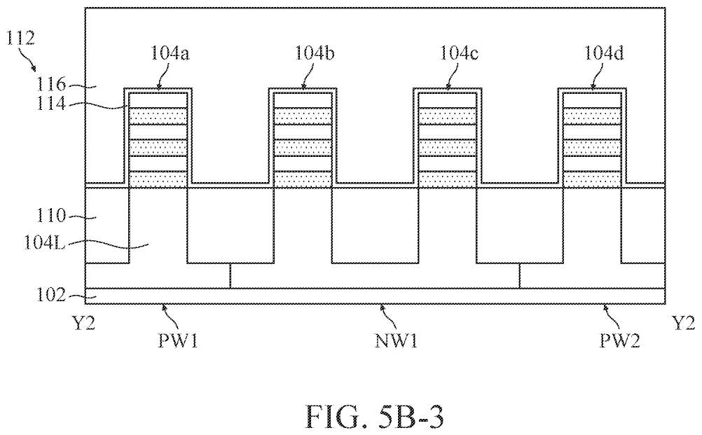

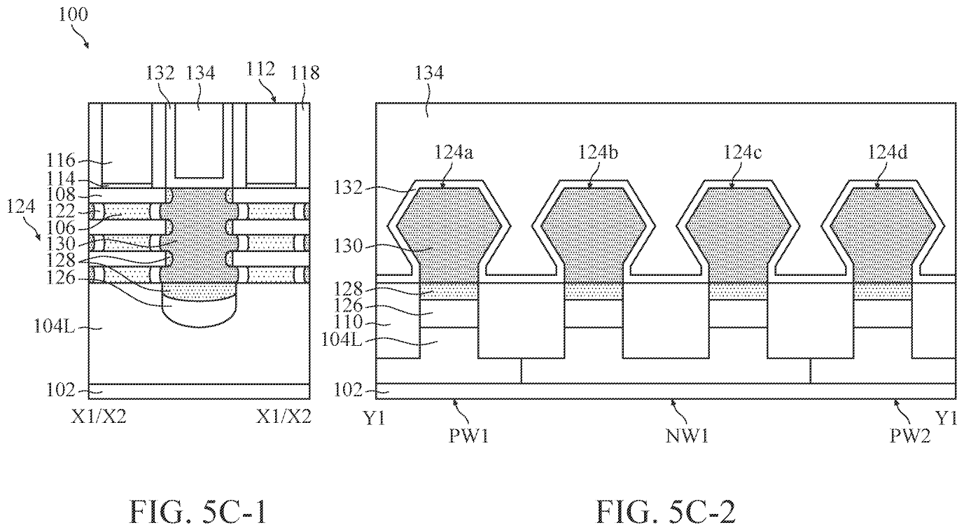

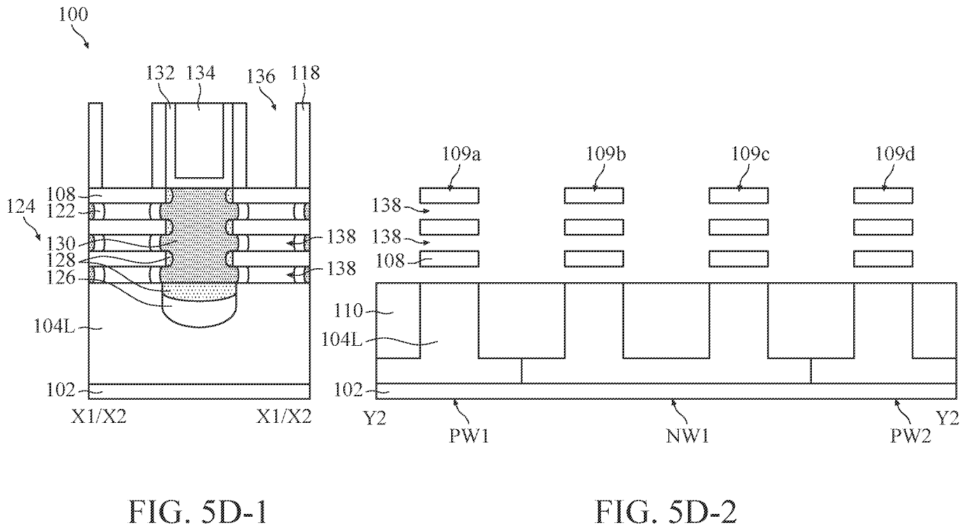

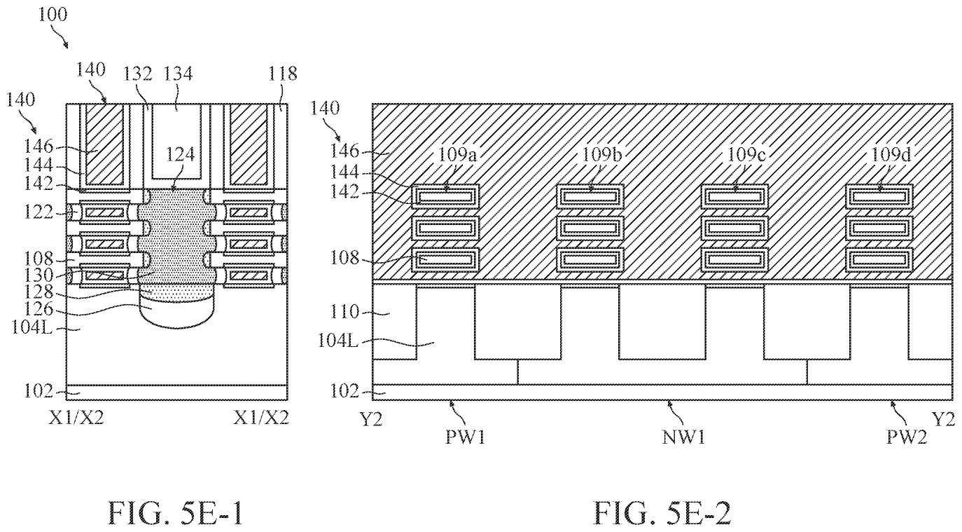

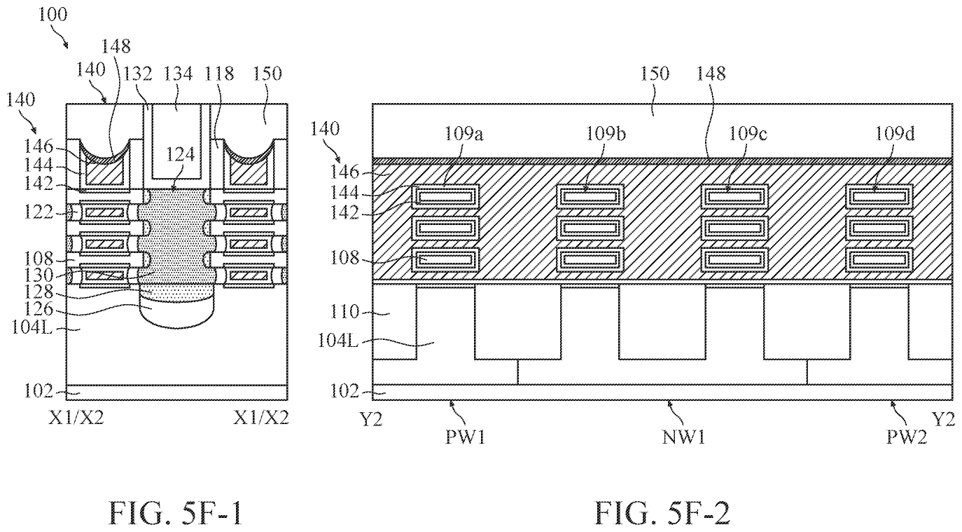

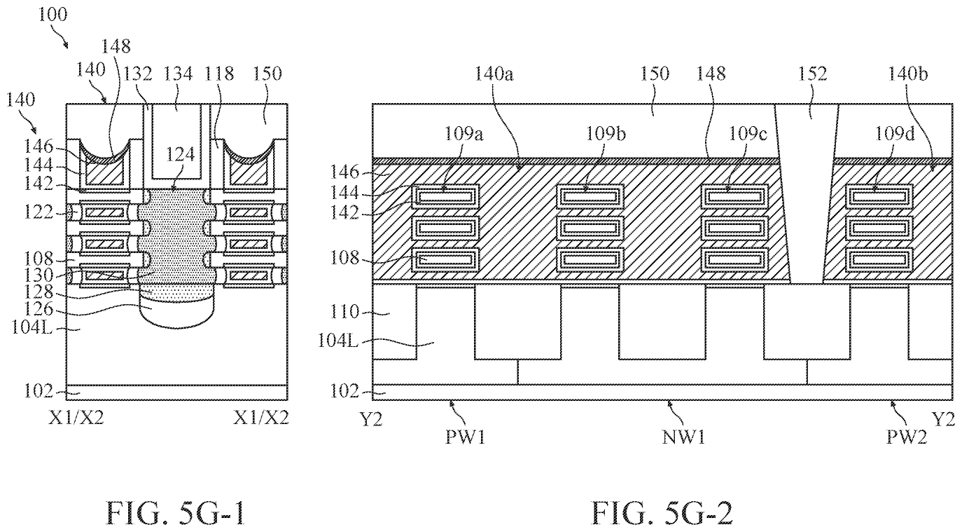

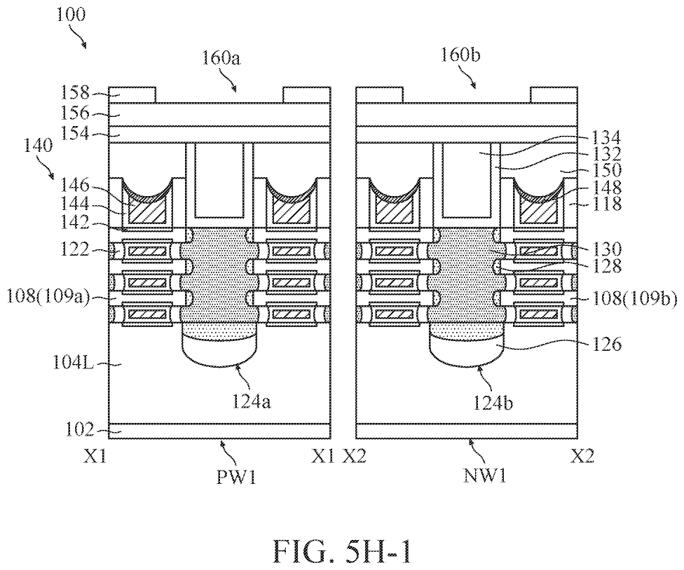

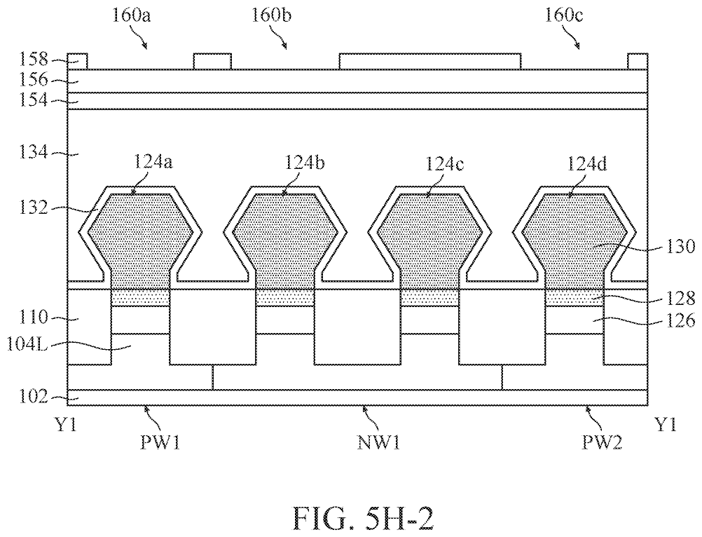

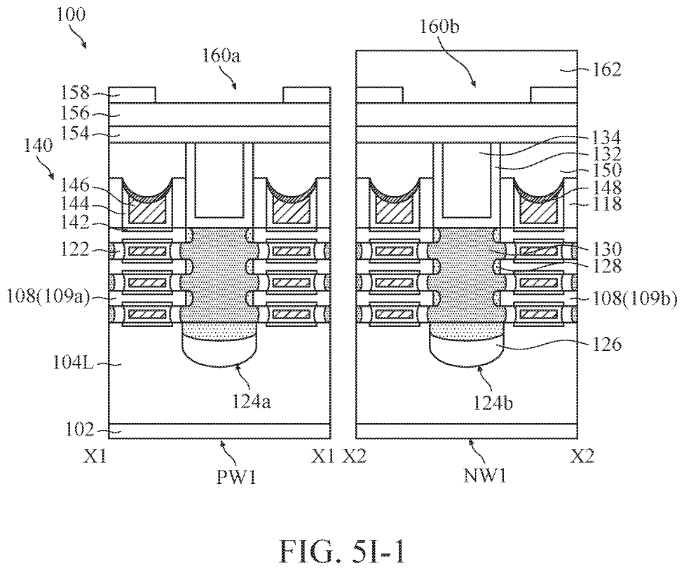

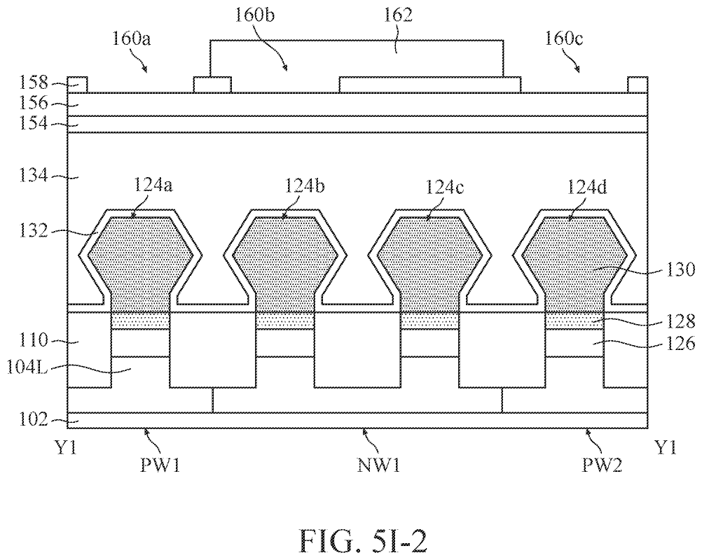

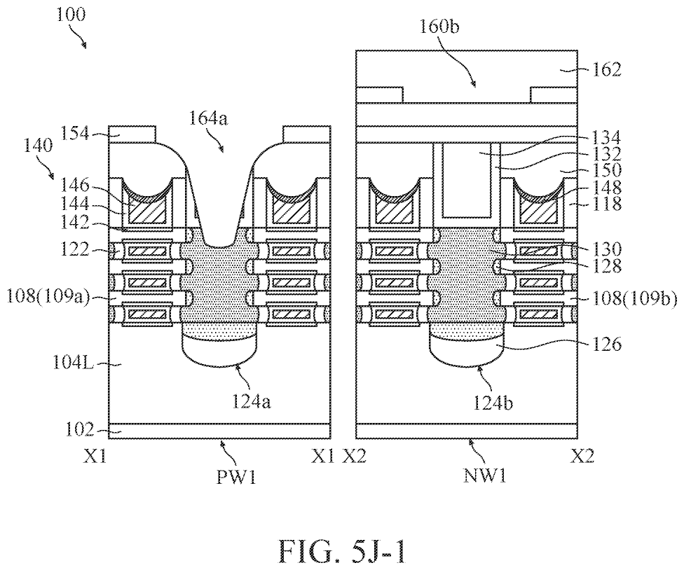

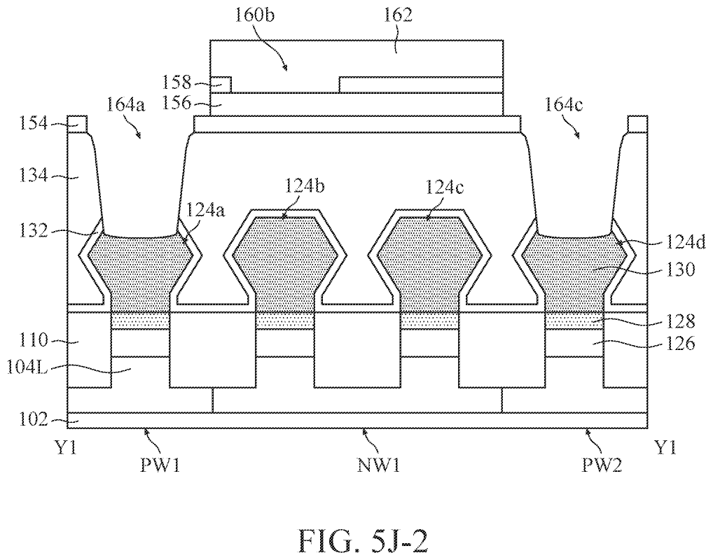

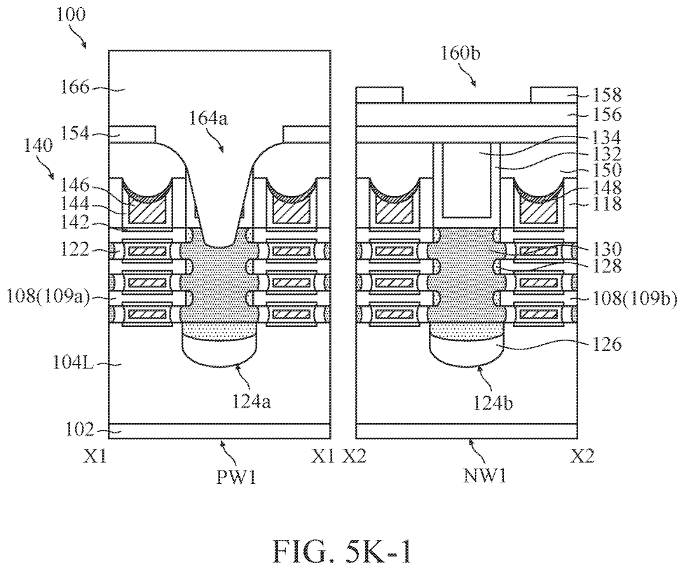

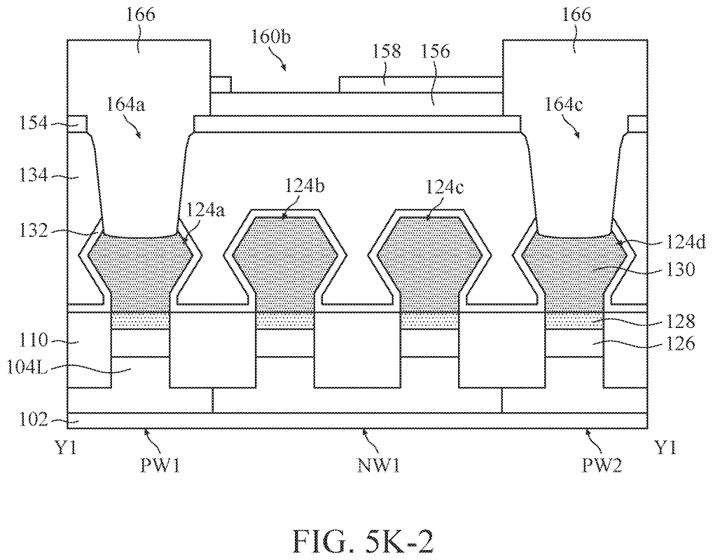

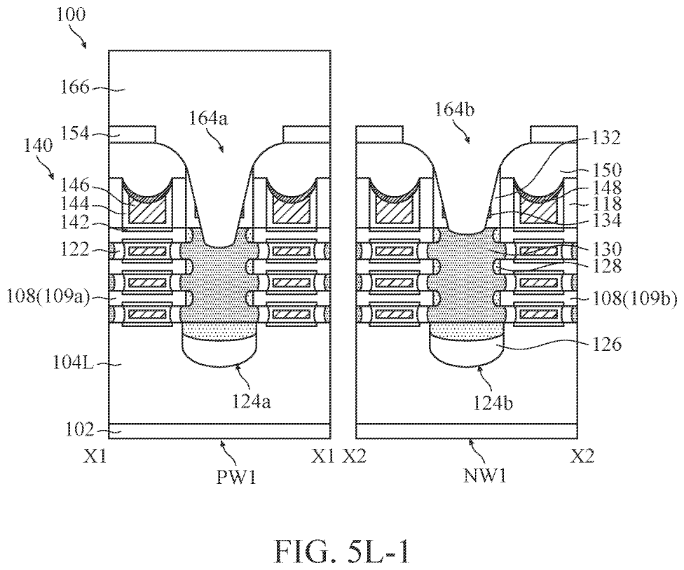

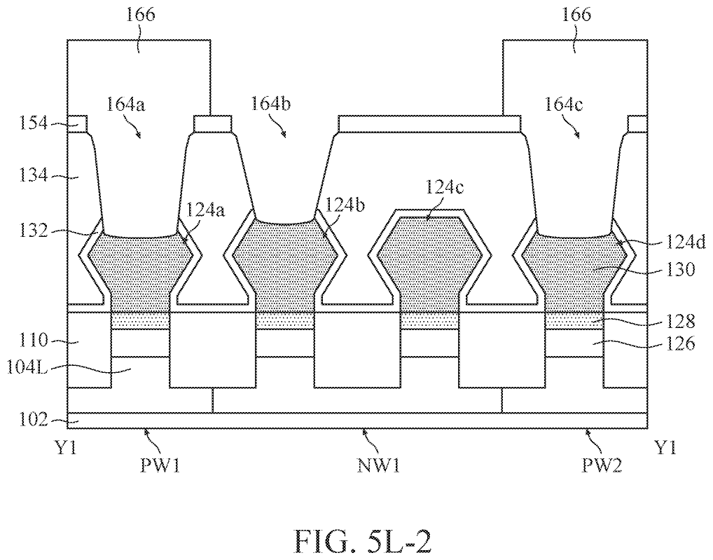

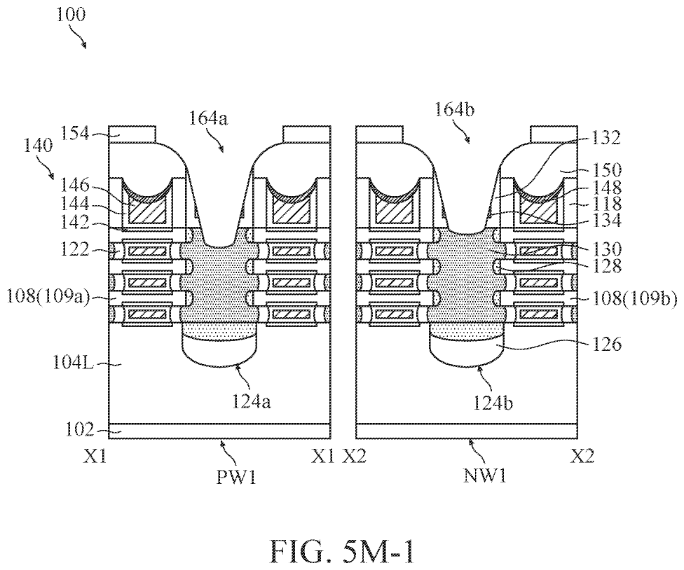

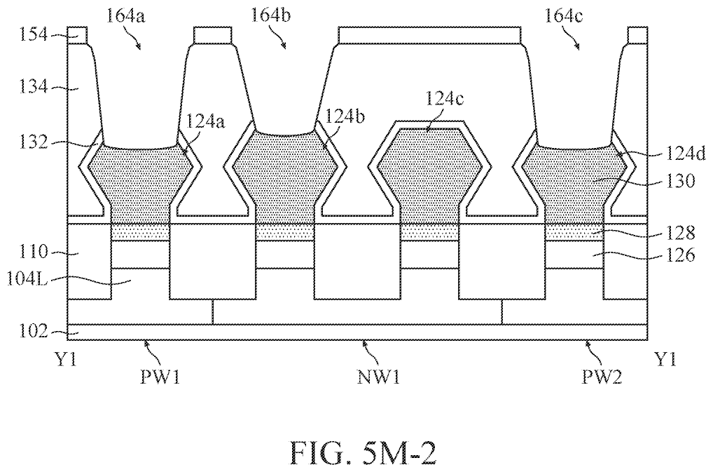

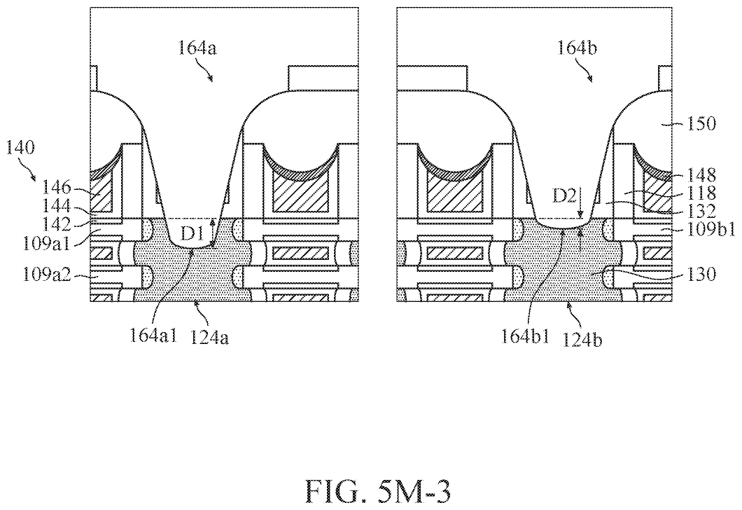

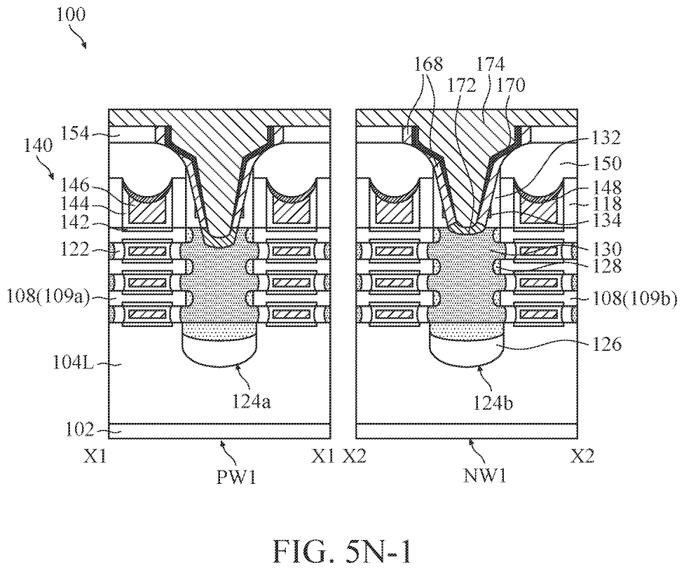

FIGS. 5A-1 through 5O-3 are cross-sectional views illustrating the formation of a semiconductor structure 100 of an SRAM cell at various intermediate stages, in which FIGS. 5A-1, 5B-1, 5C-1, 5D-1, 5E-1, 5F-1, 5G-1, 5H-1, 5I-1, 5J-1, 5K-1, 5L-1, 5M-1, 5N-1, 5O-1 correspond to cross-section X1-X1 and/or cross-section X2-X2 shown in FIG. 4, FIGS. 5A-2, 5B-2, 5C-2, 5H-2, 5I-2, 5J-2, 5K-2, 5L-2, 5M-2, 5N-2, 5O-2 correspond to cross-section Y1-Y1 shown in FIG. 4, and FIGS. 5B-3, 5D-2, 5E-2, 5F-2, 5G-2 correspond to cross-section Y2-Y2 shown in FIG. 4, in accordance with some embodiments.

FIGS. 5A-1 and 5A-2 are cross-sectional views of a semiconductor structure 100 after the formation of fin structures 104 and an isolation structure 110, in accordance with some embodiments.

A substrate 102 is provided, as shown in FIGS. 5A-1 and 5A-2, in accordance with some embodiments. The substrate 102 may be a portion of a semiconductor wafer, a semiconductor chip (or die), and the like. In some embodiments, the substrate 102 is a silicon substrate. In some embodiments, the substrate 102 includes an elementary semiconductor such as germanium; a compound semiconductor such as gallium nitride (GaN), silicon carbide (SiC), gallium arsenide (GaAs), gallium phosphide (GaP), indium phosphide (InP), indium arsenide (InAs), and/or indium antimonide (InSb); an alloy semiconductor such as SiGe, GaAsP, AlInAs, AlGaAs, GaInAs, GaInP, and/or GaInAsP; or a combination thereof. Furthermore, the substrate 102 may optionally include an epitaxial layer (epi-layer), may be strained for performance enhancement, may include a silicon-on-insulator (SOI) structure, and/or have other suitable enhancement features.

An N-type well region NW1 and two P-type well regions PW1 and PW2 are formed in the substrate 102, as shown in FIG. 5A-2, in accordance with some embodiments. In some embodiments, the N-type well region NW1 and the P-type well regions PW1 and PW2 have different electrically conductive type.

In some embodiments, the N-type well region NW1 and the P-type well regions PW1 and PW2 are formed by ion implantation processes. For example, a patterned mask layer (such as photoresist layer and/or hard mask layer) is formed to cover regions of the substrate 102 where the P-type well regions are predetermined to be formed, and then n-type dopants (such as phosphorus or arsenic) are implanted into the substrate 102, thereby forming the N-type well region NW1, in accordance with some embodiments. Similarly, a patterned mask layer (such as photoresist layer and/or hard mask layer) is formed to cover regions of the substrate 102 where the N-type well regions are predetermined to be formed, and then p-type dopants (such as boron or BF₂) are implanted into the substrate 102, thereby forming the P-type well regions PW1 and PW2, in accordance with some embodiments.

Fin structures 104 are formed over the substrate 102, as shown in FIG. 5A-2, in accordance with some embodiments. A fin structure 104a is formed over the P-type well region PW1, two fin structures 104b and 104c are formed over the N-type well region NW1, and a fin structure 104d is formed over the P-type well region PW2, in accordance with some embodiments. In some embodiments, the fin structures 104a-104d extend in the X direction. That is, the fin structures 104a-104d have longitudinal axes parallel to the X direction, in accordance with some embodiments.

The formation of the fin structures 104a-104d includes forming an epitaxial stack over the substrate 102 using an epitaxial growth process, in accordance with some embodiments. The epitaxial stack includes alternating first semiconductor layers 106 and second semiconductor layers 108, in accordance with some embodiments. The epitaxial growth process may be molecular beam epitaxy (MBE), metal organic chemical vapor deposition (MOCVD), or vapor phase epitaxy (VPE), or another suitable technique.

In some embodiments, the first semiconductor layers 106 are made of a first semiconductor material and the second semiconductor layers 108 are made of a second semiconductor material. The first semiconductor material for the first semiconductor layers 106 has a different lattice constant than the second semiconductor material for the second semiconductor layers 108, in accordance with some embodiments. In some embodiments, the first semiconductor material and the second semiconductor material have different oxidation rates and/or etching selectivity. In some embodiments, the first semiconductor layers 106 are made of SiGe, where the percentage of germanium (Ge) in the SiGe is in a range from about 20 atomic % to about 50 atomic %, and the second semiconductor layers 108 are made of pure or substantially pure silicon. In some embodiments, the first semiconductor layers 106 are Si₁₋ₓGeₓ, where x is more than about 0.3, or Ge (x=1.0) and the second semiconductor layers 108 are Si or Si_{1-y}Ge_{y}, where y is less than about 0.4, and x>y.

The first semiconductor layers 106 are configured as sacrificial layers and will be removed to form gaps to accommodate gate materials, and the second semiconductor layers 108 will form nanostructures (e.g., nanowires or nanosheets) that laterally extend between source/drain features and serve as the channel for the resulting semiconductor device (such as a nanostructure transistor), in accordance with some embodiments.

In some embodiments, the thickness of each of the first semiconductor layers 106 is in a range from about 5 nm to about 20 nm. In some embodiments, the thickness of each of the second semiconductor layers 108 is in a range from about 5 nm to about 20 nm. The thickness of the second semiconductor layers 108 may be greater than, equal to, or less than the second protection layer 108, depending on the amount of gate materials to be filled in spaces where the first semiconductor layers 106 are removed. Although three first semiconductor layers 106 and three second semiconductor layers 108 are shown in FIGS. 5A-1 and 5A-2, the numbers are not limited to three, and can be 1, 2, or more than 3, and is less than 20.

The epitaxial stack including the first semiconductor layers 106 and the second semiconductor layers 108 are then patterned into the fin structures 104a-104d, in accordance with some embodiments. In some embodiments, the patterning process includes forming a patterned hard mask layer (not shown) over the epitaxial stack. An etching process is then performed to remove portions of the epitaxial stack and underlying substrate 102 uncovered by the patterned hard mask layer, thereby forming trenches and the fin structures 104a-104d protruding from between the trenches, in accordance with some embodiments. The etching process may be an anisotropic etching process, e.g., dry plasma etching.

The portion of the substrate 102 protruding from between the trenches forms lower fin elements 104L of the fin structures 104a-104d, in accordance with some embodiments. A remainder of the epitaxial stack (including the first semiconductor layers 106 and the second semiconductor layers 108) forms the upper fin elements of the fin structures 104a-104d over the respective lower fin elements 104L, in accordance with some embodiments.

An isolation structure 110 is formed to surround the lower fin elements 104L of the fin structures 104a-104d, as shown in FIG. 5A-2, in accordance with some embodiments. The isolation structure 110 is configured to electrically isolate active regions (e.g., the fin structures 104a-104d) of the semiconductor structure 100 and is also referred to as shallow trench isolation (STI) feature, in accordance with some embodiments.

The formation of the isolation structure 110 includes forming an insulating material to overfill the trenches, in accordance with some embodiments. In some embodiments, the insulating material is made of silicon oxide, silicon nitride, silicon oxynitride (SiON), another suitable insulating material, multilayers thereof, and/or a combination thereof. In some embodiments, the insulating material is deposited using includes CVD (such as low-pressure CVD (LPCVD), plasma-enhanced CVD (PECVD), high density plasma CVD (HDP-CVD), high aspect ratio process (HARP), or flowable CVD (FCVD)), atomic layer deposition (ALD), another suitable technique, and/or a combination thereof.

A planarization process is performed on the insulating material to remove a portion of the insulating material above the patterned hard mask layer (not shown) until the patterned hard mask layer is exposed, in accordance with some embodiments. In some embodiments, the patterned hard mask layer is also removed in the planarization process, and the upper surfaces of the fin structures 104a-104d are exposed. The planarization may be chemical mechanical polishing (CMP), etching back process, or a combination thereof.

The insulating material is then recessed by an etching process (such as dry plasma etching and/or wet chemical etching) until the upper fin elements of the fin structures 104a-104d are exposed, in accordance with some embodiments. The recessed insulating material serves as the isolation structure 110, in accordance with some embodiments.

FIGS. 5B-1, 5B-2 and 5B-3 are cross-sectional views of a semiconductor structure 100 after the formation of dummy gate structures 112, source/drain recesses 120 and inner spacer layers 122, in accordance with some embodiments.

Dummy gate structures 112 are formed over the semiconductor structure 100, as shown in FIGS. 5B-1 and 5B-3, in accordance with some embodiments. The dummy gate structures 112 extend across and surrounds the channel regions of the fin structures 104a-104d to define the channel regions and the source/drain regions, in accordance with some embodiments. The dummy gate structures 112 are configured as sacrificial structures and will be replaced with final gate stacks, in accordance with some embodiments. In some embodiments, the dummy gate structures 112 extend in Y direction. That is, the dummy gate structures 112 have longitudinal axes parallel to the Y direction, in accordance with some embodiments.

Each of the dummy gate structures 112 includes a dummy gate dielectric layer 114 and a dummy gate electrode layer 116 formed over the dummy gate dielectric layer 114, as shown in FIGS. 5B-1 and 5B-3, in accordance with some embodiments. In some embodiments, the dummy gate dielectric layer 114 is made of one or more dielectric materials, such as silicon oxide (SiO), silicon nitride (SiN), silicon oxynitride (SiON), HfO₂, HfZrO, HfSiO, HfTiO, HfAlO, and/or a combination thereof. In some embodiments, the dielectric material is formed using ALD, CVD, thermal oxidation, physical vapor deposition (PVD), another suitable technique, and/or a combination thereof.

In some embodiments, the dummy gate electrode layer 116 is made of semiconductor material such as polysilicon, poly-silicon germanium. In some embodiments, the dummy gate electrode layer 116 is made of a conductive material such as metallic nitrides, metallic silicides, metals, and/or a combination thereof. In some embodiments, the material for the dummy gate electrode layer 116 is formed using CVD, another suitable technique, and/or a combination thereof.

In some embodiments, the formation of the dummy gate structures 112 include globally and conformally depositing a dielectric material for the dummy gate dielectric layer 114 over the semiconductor structure 100, depositing a material for the dummy gate electrode layer 116 over the dielectric material, planarizing the material for the dummy gate electrode layer 116, and patterning the dielectric material and the material for the dummy gate electrode layer 116 into the dummy gate structures 112. The patterning process includes forming a patterned hard mask layer (not shown) over the material for the dummy gate electrode layer 116 to cover the channel regions of the fin structures 104a-104d, in accordance with some embodiments. The material for the dummy gate electrode layer 116 and dielectric material, uncovered by the patterned hard mask layer, is etched away until the source/drain regions of the fin structures 104a-104d are exposed, in accordance with some embodiments.

The gate spacer layers 118 are formed over the semiconductor structure 100, as shown in FIG. 5B-1, in accordance with some embodiments. The gate spacer layers 118 are formed on the opposite sides of the dummy gate structures 112, in accordance with some embodiments. The gate spacer layers 118 are used to offset the subsequently formed source/drain features and separate the source/drain features from the gate structure, in accordance with some embodiments.

In some embodiments, the gate spacer layers 118 are made of a silicon-containing dielectric material, such as silicon oxide (SiO₂), silicon nitride (SiN), silicon carbide (SiC), silicon oxynitride (SiON), silicon carbon nitride (SiCN), silicon oxycarbonitride (SiOCN), and/or oxygen-doped silicon carbonitride (Si(O)CN). In some embodiments, the formation of the gate spacer layers 118 includes globally and conformally depositing a dielectric material for the gate spacer layers 118 over the semiconductor structure 100 using ALD, CVD, another suitable method, and/or a combination thereof, followed by an anisotropic etching process such as dry etching. Portions of the dielectric material leaving on the sidewalls of the dummy gate structures 112 serve as the gate spacer layers 118, in accordance with some embodiments.

Afterward, an etching process is performed using the gate spacers 118 and the dummy gate structures 112 as etch mask to recess the source/drain regions of the fin structures 104a-104d, such that source/drain recesses 120 are formed self-aligned on the opposite sides of the dummy gate structures 112, as shown in FIGS. 5B-1 and 5B-2, in accordance with some embodiments. The etching process may be an anisotropic etching process such as dry plasma etching. In some embodiments, the etching processes are performed without an additional photolithography process.

A source/drain recess 120a is formed in the fin structure 104a, a source/drain recess 120b is formed in the fin structure 104b, a source/drain recess 120c is formed in the fin structure 104c, and a source/drain recess 120d is formed in the fin structure 104d, as shown in FIG. 5B-2, in accordance with some embodiments. The source/drain recesses 120a-120d pass through the upper fin element of the fin structure 104 and extend into the lower fin elements 104L, in accordance with some embodiments. The bottom surfaces of the source/drain recesses 120a-120d may extend to a position below the upper surface of the isolation structure 110, in accordance with some embodiments.

Afterward, an etching process is performed on the semiconductor structure 100 to laterally recess, from the source/drain recesses 120a-120d, the first semiconductor layers 106 of the fin structures 104a-104d to form notches. In some embodiments, in the etching process, the first semiconductor layers 106 have a greater etching rate than the second semiconductor layers 108, thereby forming notches between adjacent second semiconductor layers 108 and between the lowermost second semiconductor layer 108 and the lower fin element 104L. In some embodiments, the etching process is an isotropic etching such as dry chemical etching, remote plasma etching, wet chemical etching, another suitable technique, and/or a combination thereof.

Inner spacer layers 122 are then formed in the notches, as shown in FIG. 5B-1, in accordance with some embodiments. The inner spacer layers 122 are formed to abut the recessed side surfaces of the first semiconductor layers 106, in accordance with some embodiments. In some embodiments, the inner spacer layers 122 extend, from the source/drain regions toward the channel region, directly below the gate spacer layers 118, in accordance with some embodiments.

The inner spacer layers 122 interpose subsequently formed source/drain features and gate stack to avoid the source/drain features and the gate stack from being in direct contact and are configured to reduce the parasitic capacitance between the metal gate stack and the source/drain features (i.e. Cgs and Cgd), in accordance with some embodiments.

In some embodiments, the inner spacer layers 122 are made of a silicon-containing dielectric material, such as silicon oxide (SiO₂), silicon nitride (SiN), silicon carbide (SiC), silicon oxynitride (SiON), silicon carbon nitride (SiCN), silicon oxycarbonitride (SiOCN), and/or oxygen-doped silicon carbonitride (Si(O)CN). In some embodiments, the inner spacer layers 122 are made of low-k dielectric materials. For example, the dielectric constant (k) values of the inner spacer layers 122 may be lower than a k-value of silicon oxide (SiO), such as lower than 4.2, equal to or lower than about 3.9, such as in a range from about 3.5 to about 3.9.

In some embodiments, the inner spacer layers 122 are formed by globally and conformally depositing a dielectric material for the inner spacer layers 122 over the semiconductor structure 100 to fill the notches, and then etching back the dielectric material to remove the dielectric material outside the notches. Portions of the dielectric material leaving in the notches serve as the inner spacer layers 122, in accordance with some embodiments. In some embodiments, the deposition process includes ALD, CVD (such as PECVD, LPCVD or HARP), another suitable technique, and/or a combination thereof. In some embodiments, the etching back process includes an anisotropic etching process such as dry plasma etching, an isotropic etching process such as dry chemical etching, remote plasma etching or wet chemical etching, and/or a combination thereof.

FIGS. 5C-1 and 5C-2 are cross-sectional views of a semiconductor structure 100 after the formation of source/drain features 124, contact etching stop layer (CESL) 132 and lower interlayer dielectric layer (ILD) 134, in accordance with some embodiments.

Source/drain features 124 are formed in the source/drain recesses 120a-120d over the lower fin elements 104L of the fin structures 104 using an epitaxial growth process, as shown in FIGS. 5C-1 and 5C-2, in accordance with some embodiments. The source/drain features 124 are formed on opposite sides of the dummy gate structures 112, in accordance with some embodiments. The epitaxial growth process may be MBE, MOCVD, or VPE, another suitable technique, or a combination thereof.

Source/drain features 124a are formed over the fin structure 104a, source/drain features 124b are formed over the fin structure 104b, source/drain features 124c are formed over the fin structure 104c, source/drain features 124d are formed over the fin structure 104d, as shown in FIG. 5C-2, in accordance with some embodiments. In some embodiments, the source/drain features 124a and 124d have a different electrically conductive type than the source/drain features 124b and 124c.

In some embodiments, the source/drain features 124a and 124d and the source/drain features 124b and 124c may be formed separately. For example, a patterned mask layer (such as photoresist layer and/or hard mask layer) may be formed to cover the P-type well regions PW1 and PW2, and then the source/drain features 124b and 124c are grown on the fin structures 104b and 104c. Similarly, a patterned mask layer (such as photoresist layer and/or hard mask layer) is formed to cover the N-type well region NW1, and then the source/drain features 124a and 124d are grown on the fin structures 104a and 104d. In some embodiments, the source/drain features 124a-124d are in-situ doped during the epitaxial processes.

Each of the source/drain features 124a-124d includes an undoped layer 126 formed on the lower fin elements 104L, barrier layers 128 formed on the undoped layer 126 and the second semiconductor layers 108, and a bulk layer 130 filling the remainder of the source/drain recess 120, in accordance with some embodiments.

In some embodiments, the undoped layer 126 may be intrinsic semiconductor material such as silicon, silicon germanium and/or another suitable semiconductor material. For example, an impurity (or an n-type dopant and/or a p-type dopant) in the undoped layer 126 has a concentration of less than about 10¹⁴ cm⁻³. In some embodiments, the undoped layer 126 is configured as an insulating layer to reduce leakage between adjacent devices from through the substrate 102.

In some embodiments, the barrier layers 128 and the bulk layer 130 are doped. The concentration of the dopant in the bulk layer 130 is higher than the concentration of the dopant in the barrier layers 128, e.g., by 2 orders, in accordance with some embodiments. In some embodiments, the dopant in the barrier layers 128 has a concentration in a range from about 1×10¹⁹ cm⁻³ to about 6×10¹⁹ cm⁻³, and the dopant in the bulk layer 130 of the source/drain feature has a concentration in a range from about 1×10²¹ cm⁻³ to about 6×10²¹ cm⁻³.

In some embodiments, the barrier layers 128 with relatively a low dopant concentration are configured to block the dopant from the bulk layer 130 with relatively high dopant concentration from diffusing into the second semiconductor layers 108. In some embodiments, the bulk layer 130 with a relatively high dopant concentration may reduce contact resistance.

In some embodiments, the barrier layer 128 and the bulk layer 130 of the source/drain features 124a and 124d, formed in the P-type well regions PW1 and PW2, are doped with the n-type dopant during the epitaxial growth process. For example, the n-type dopant may be phosphorous (P) or arsenic (As). For example, the barrier layers 128 and the bulk layer 130 of the source/drain features 124a and 124d may be the epitaxially grown Si doped with phosphorous to form silicon:phosphor (Si:P) source/drain features and/or arsenic to form silicon:arsenic (Si:As) source/drain feature.

In some embodiments, the barrier layers 128 and the bulk layer 130 of the source/drain features 124b and 124c, formed in the N-type well region NW1, are doped with the with the p-type dopant during the epitaxial growth process. For example, the p-type dopant may be boron (B) or BF₂. For example, the barrier layers 128 and the bulk layer 130 of the source/drain features 124b and 124c may be the epitaxially grown SiGe doped with boron (B) to form silicon germanium:boron (SiGe:B) source/drain feature.

A contact etching stop layer 132 is formed over the semiconductor structure 100, as shown in FIGS. 5C-1 and 5C-2, in accordance with some embodiments. In some embodiments, the contact etching stop layer 132 is made of dielectric material, such as silicon nitride (SiN), silicon oxide (SiO₂), silicon oxynitride (SiOC), silicon carbide (SiC), oxygen-doped silicon carbide (SiC:O), oxygen-doped silicon carbonitride (Si(O)CN), or a combination thereof. In some embodiments, a dielectric material for the contact etching stop layer 132 is globally and conformally deposited over the semiconductor structure 100 using CVD (such as LPCVD, PECVD, HDP-CVD, or HARP), ALD, another suitable method, or a combination thereof.

Afterward, a lower interlayer dielectric layer 134 is formed over the contact etching stop layer 132 to fill spaces between the dummy gate structures 112, as shown in FIGS. 5C-1 and 5C-2, in accordance with some embodiments. In some embodiments, the lower interlayer dielectric layer 134 is made of dielectric material, such as un-doped silicate glass (USG), doped silicon oxide such as borophosphosilicate glass (BPSG), fluoride-doped silicate glass (FSG), phosphosilicate glass (PSG), borosilicate glass (BSG), and/or another suitable dielectric material. In some embodiments, the lower interlayer dielectric layer 134 and the contact etching stop layer 132 are made of different materials and have a great difference in etching selectivity. In some embodiments, the dielectric material for the lower interlayer dielectric layer 134 is deposited using such as CVD (such as HDP-CVD, PECVD, HARP or FCVD), another suitable technique, and/or a combination thereof.

The dielectric materials for the contact etching stop layer 132 and the lower interlayer dielectric layer 134 above the upper surface of the dummy gate electrode layer 116 are removed using such as CMP until the upper surface of the dummy gate electrode layer 116 is exposed, in accordance with some embodiments. In some embodiments, the upper surface of the lower interlayer dielectric layer 134 is substantially coplanar with the upper surfaces of the dummy gate electrode layer 116.

FIGS. 5D-1 and 5D-2 are cross-sectional views of a semiconductor structure 100 after the formation of gate trenches 136 and gaps 138, in accordance with some embodiments.

The dummy gate structures 116 are removed using one or more etching processes to form gate trenches 136, as shown in FIG. 5D-1, in accordance with some embodiments. The gate trenches 136 expose the channel regions of the fin structures 104a-104d, in accordance with some embodiments. In some embodiments, the gate trenches 136 also expose the inner sidewalls of the gate spacer layers 118 facing the channel region, in accordance with some embodiments.

In some embodiments, the etching process includes one or more etching processes. For example, when the dummy gate electrode layers 116 is made of polysilicon, a wet etchant such as a tetramethylammonium hydroxide (TMAH) solution may be used to selectively remove the dummy gate electrode layers 116. For example, the dummy gate dielectric layer 114 may be thereafter removed using a plasma dry etching, a dry chemical etching, and/or a wet etching.

The first semiconductor layers 106 of the fin structures 104a-104d are removed using an etching process to form gaps 138, as shown in FIGS. 5D-1 and 5D-2, in accordance with some embodiments. The inner spacer layers 122 may be used as an etching stop layer in the etching process, which may protect the source/drain features 124 from being damaged. The gaps 138 are located between the neighboring second semiconductor layers 108 and between the lowermost second semiconductor layer 108 and the lower fin elements 104L of the fin structures 104a-104d, in accordance with some embodiments. In some embodiments, the gaps 138 also expose the inner sidewalls of the inner spacer layers 122 facing the channel region.

After the etching process, the four main surfaces of the second semiconductor layers 108 are exposed, in accordance with some embodiments. The exposed second semiconductor layers 108 of the fin structures 104a-104d form four sets of nanostructures 109a-109d, respectively, that function as channel layers of the resulting semiconductor devices (e.g., nanostructure transistors such as GAA FETs), in accordance with some embodiments.

In some embodiments, the etching process includes a selective wet etching process, such as APM (e.g., ammonia hydroxide-hydrogen peroxide-water mixture) etching process. In some embodiments, the wet etching process uses etchants such as ammonium hydroxide (NH₄OH), TMAH, ethylenediamine pyrocatechol (EDP), and/or potassium hydroxide (KOH) solutions.

FIGS. 5E-1 and 5E-2 are cross-sectional views of a semiconductor structure 100 after the formation of final gate stacks 140, in accordance with some embodiments.

Interfacial layer 142 is formed on the exposed surfaces of the nanostructures 109a-109d and the upper surfaces of the lower fin elements 104L, as shown in FIGS. 5E-1 and 5E-2, in accordance with some embodiments. The interfacial layer 142 wraps around the nanostructures 109a-109d, in accordance with some embodiments.

In some embodiments, the interfacial layer 142 is made of a chemically formed silicon oxide. In some embodiments, the interfacial layer 154 is formed using one or more cleaning processes such as including ozone (O₃), ammonia hydroxide-hydrogen peroxide-water mixture, and/or hydrochloric acid-hydrogen peroxide-water mixture. Semiconductor material from the nanostructures 109a-109d and the lower fin elements 104L is oxidized to form the interfacial layer 142, in accordance with some embodiments.

A gate dielectric layer 144 is formed conformally along the interfacial layer 142 to wrap around the nanostructures 109a-109d, as shown in FIGS. 5E-1 and 5E-2, in accordance with some embodiments. The gate dielectric layer 144 is also formed along the upper surface of the isolation structure 110, in accordance with some embodiments. The gate dielectric layer 144 is also conformally formed along the inner sidewalls of the gate spacer layers 118 facing the channel region, in accordance with some embodiments. The gate dielectric layer 144 is also conformally formed along the inner sidewalls of the inner spacer layers 122 facing the channel region, in accordance with some embodiments.

The gate dielectric layer 144 may be high-k dielectric layer. In some embodiments, the high-k dielectric layer is made of a dielectric material with high dielectric constant (k value), for example, greater than 3.9. In some embodiments, the high-k dielectric layer includes hafnium oxide (HfO₂), TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba,Sr)TiO₃ (BST), Al₂O₃, Si₃N₄, oxynitrides (SiON), a combination thereof, or another suitable material. The high-k dielectric layer may be deposited using ALD, PVD, CVD, and/or another suitable technique.

A metal gate electrode layer 146 is formed over the gate dielectric layer 144 and fills remainders of the gate trenches 136 and the gaps 138, as shown in FIGS. 5E-1 and 5E-2, in accordance with some embodiments. The metal gate electrode layer 146 wraps around the nanostructures 109, in accordance with some embodiments.

In some embodiments, the metal gate electrode layer 146 is made of more than one conductive material, such as a metal, metal alloy, conductive metal oxide and/or metal nitride, another suitable conductive material, and/or a combination thereof. For example, the metal gate electrode layer 146 may be made of Ti, Ag, Al, TiAlN, TaC, TaCN, TaSiN, Mn, Zr, TiN, TaN, Ru, Mo, Al, WN, Cu, W, Re, Ir, Co, Ni, another suitable conductive material, or multilayers thereof.

The metal gate electrode layer 146 may be a multi-layer structure with various combinations of a diffusion barrier layer, work function layers with a selected work function to enhance the device performance (e.g., threshold voltage) for n-channel nanostructure transistors or p-channel nanostructure transistors, a capping layer to prevent oxidation of work function layers, a glue layer to adhere work function layers to a next layer, and a metal fill layer to reduce the total resistance of gate stacks, and/or another suitable layer. The metal gate electrode layer 146 may be formed using ALD, PVD, CVD, e-beam evaporation, or another suitable process. Different work function materials may be used for n-channel nanostructure transistors and p-channel nanostructure transistors.

A planarization process such as CMP may be performed on the semiconductor structure 100 to remove the materials of the gate dielectric layer 144 and the metal gate electrode layer 146 formed above the upper surface of the lower interlayer dielectric layer 134, in accordance with some embodiments. After the planarization process, the upper surface of the metal gate electrode layer 146 and the upper surface of the lower interlayer dielectric layer 134 are substantially coplanar, in accordance with some embodiments.

The interfacial layer 142, the gate dielectric layer 144 and the metal gate electrode layer 146 combine to form final gate stacks 140, as shown in FIGS. 5E-1 and 5E-2, in accordance with some embodiments. In some embodiments, the final gate stack 140 extends in the Y direction. That is, the final gate stacks 140 have longitudinal axes parallel to the Y direction, in accordance with some embodiments. The final gate stack 140 wraps around each of the nanostructures 109 and is interposed between the source/drain features 124, in accordance with some embodiments.

The portion of the final gate stack 140 wrapping around the set of nanostructures 109a combines with the source/drain features 124a to form an n-channel nanostructure transistor which may serve as the pull-down transistor PD-2 shown in FIG. 3, in accordance with some embodiments.

The portion of the final gate stack 140 wrapping around the set of nanostructures 109b combines with the source/drain features 124b to form a p-channel nanostructure transistor which may serve as the pull-up transistor PU-2 shown in FIG. 3, in accordance with some embodiments.

The portion of the final gate stack 140 wrapping around the set of nanostructures 109c combines with the source/drain features 124c to form a p-channel nanostructure transistor which may serve as the isolation transistors IS-1 shown in FIG. 3, in accordance with some embodiments.

The portion of the final gate stack 140 wrapping around the set of nanostructures 109d combines with the source/drain features 124d to form an n-channel nanostructure transistor which may serve as the pass-gate transistor PG-1 shown in FIG. 3, in accordance with some embodiments.

FIGS. 5F-1 and 5F-2 are cross-sectional views of a semiconductor structure 100 after the formation of metal capping layers 148 and dielectric capping layers 150, in accordance with some embodiments.

An etching process is performed to recess the final gate stacks 140 and the gate spacer layers 118, thereby forming recesses within the lower interlayer dielectric layer 134, in accordance with some embodiments. The etching process may be an anisotropic etching process such as dry plasma etching, an isotropic etching process such as dry chemical etching, remote plasma etching or wet chemical etching, and/or a combination thereof.

Metal capping layers 148 are formed over the upper surfaces of the recessed final gate stacks 140 using a deposition process and an etching back process, as shown in FIGS. 5F-1 and 5F-2, in accordance with some embodiments. In some embodiments, the metal capping layers 148 are made of metal such as W, Re, Ir, Co, Ni, Ru, Mo, Al, Ti, Ag, Al, another suitable metal, or multilayers thereof. In some embodiments, the metal capping layers 148 and the metal gate electrode layer 146 are made of different materials. In some embodiments, the metal capping layers 148 are made of fluorine-free tungsten, which may lower the total resistance of the gate stack.

Afterward, dielectric capping layers 150 are formed in the recesses over the metal capping layers 148 and the gate spacer layers 118, as shown in FIGS. 5F-1 and 5F-2, in accordance with some embodiments. The dielectric capping layers 150 may be configured to protect the gate spacer layers 118 and the final gate stacks 140 during the subsequent etching process for forming contact plugs.

The dielectric capping layers 150 are made of dielectric material such as silicon nitride (SiN), silicon oxynitride (SiON), silicon carbon nitride (SiCN), silicon oxycarbonitride (SiOCN), oxygen-doped silicon carbonitride (Si(O)CN), silicon oxide (SiO₂), or a combination thereof. In some embodiments, the dielectric material for the dielectric capping layers 150 is deposited using such as ALD, CVD (such as LPCVD, PECVD, HDP-CVD, or HARP), another suitable technique, and/or a combination thereof. Afterward, a planarization process is then performed on the dielectric capping layers 150 until the lower interlayer dielectric layer 134 is exposed, in accordance with some embodiments. The planarization may be CMP, etching back process, or a combination thereof.

FIGS. 5G-1 and 5G-2 are cross-sectional views of a semiconductor structure 100 after the formation of a gate isolation structure 152, in accordance with some embodiments.

A gate isolation structure 152 is formed through the dielectric capping layer 150, the metal capping layer 148 and the final gate stack 140 and lands on the isolation structure 110, as shown in FIG. 5G-1, in accordance with some embodiments.

The formation of the gate isolation structure 152 includes forming a patterned mask layer using a photolithography process over the semiconductor structure 100, and etching the dielectric capping layer 150, the metal capping layer 148 and the final gate stack 140 to form a gate-cut opening (where the gate isolation structure 152 are to be formed) until the isolation structure 110 is exposed. The final gate stack 140 is cut through by the gate-cut opening to form two segments 140a and 140b, as shown in FIG. 5G-2, in accordance with some embodiments.

The formation of the gate isolation structure 152 also includes depositing a dielectric material for the gate isolation structure 152 to overfill the gate-cut opening, in accordance with some embodiments. The gate isolation structure 152 is made of dielectric material such as silicon nitride (SiN), silicon oxynitride (SiON), silicon carbon nitride (SiCN), silicon oxycarbonitride (SiOCN), oxygen-doped silicon carbonitride (Si(O)CN), silicon oxide (SiO₂), or a combination thereof. In some embodiments, the deposition process is ALD, CVD (such as LPCVD, PECVD, HDP-CVD, or HARP), another suitable technique, and/or a combination thereof.

Afterward, a planarization process is then performed on the dielectric material for the gate isolation structure 152 until the lower interlayer dielectric layer 134 and the dielectric capping layer 150 are exposed, in accordance with some embodiments. The planarization may be CMP, etching back process, or a combination thereof. In some embodiments, the segments 140a and 140b of the final gate stack 140 are electrically isolated from one another by the gate isolation structure 152.

FIGS. 5H-1 through 5O-3 illustrate the formation of contact plugs 178a-178c to the source/drain features, in accordance with some embodiments. In some embodiments, the contact plugs 178a-178c shown in FIGS. 5O-1, 5O-2 and 5O-3 are the same as the contact plugs 178a-178c shown in FIG. 3. In some embodiments, the contact plugs 178a and 178c formed in the P-type well regions PW1 and PW2 have a different thickness than the contact plug 178b formed in the N-type well region NW1, which may be helpful in improving the performance of the SRAM device. This will be discussed in detail later.

FIGS. 5H-1 and 5H-2 are cross-sectional views of a semiconductor structure 100 after the formation of an upper interlayer dielectric layer 154 and mask layers 156 and 158, in accordance with some embodiments.

An upper interlayer dielectric layer 154 is formed over the dielectric capping layer 150 and the lower interlayer dielectric layer 134, as shown in FIGS. 5H-1 and 5H-2, in accordance with some embodiments. In some embodiments, the upper interlayer dielectric layer 154 is made of dielectric material, such as USG, BPSG, FSG, PSG, BSG, and/or another suitable dielectric material. In some embodiments, the upper interlayer dielectric layer 154 is deposited using such as CVD (such as HDP-CVD, PECVD, HARP or FCVD), another suitable technique, and/or a combination thereof.

A first mask layer 156 is formed over the upper interlayer dielectric layer 154, as shown in FIGS. 5H-1 and 5H-2, in accordance with some embodiments. In some embodiments, the first mask layer 156 is made of dielectric material, such as dielectric material, such as silicon oxide (SiO₂), silicon nitride (SiN), silicon oxynitride (SiOC), silicon carbide (SiC), oxygen-doped silicon carbide (SiC:O), oxygen-doped silicon carbonitride (Si(O)CN), or a combination thereof, and/or another suitable dielectric material. In some embodiments, the first mask layer 156 is deposited using such as CVD (such as LPCVD, PECVD, HDP-CVD, or HARP), ALD, another suitable method, or a combination thereof.

A second mask layer 158 is formed over the first mask layer 156, as shown in FIGS. 5H-1 and 5H-2, in accordance with some embodiments. In some embodiments, the second mask layer 158 is made of semiconductor material such as silicon and/or silicon germanium. In some embodiments, the second mask layer 158 is made of a nitrogen-free anti-reflection layer (NFARL), carbon-doped silicon dioxide (e.g., SiO₂:C), titanium nitride (TiN), titanium oxide (TiO), boron nitride (BN), another suitable material, and/or a combination thereof. In some embodiments, the second mask layer 158 is deposited using such as CVD (such as LPCVD, PECVD, HDP-CVD, or HARP), ALD, another suitable method, or a combination thereof.

A patterning process is performed on the second mask layer 158 to form opening patterns 160a, 160b and 160c, as shown in FIGS. 5H-1 and 5H-2, in accordance with some embodiments. The opening patterns 160a, 160b and 160c are aligned over the source/drain features 124a, 124b and 124d, respectively, in accordance with some embodiments.

For example, a photoresist may be formed over the second mask layer 158 such as by using spin-on coating, and patterned with opening patterns corresponding to the opening patterns 160a, 160b and 160c by exposing the photoresist to light using an appropriate photomask. Exposed or unexposed portions of the photoresist may be removed depending on whether a positive or negative resist is used. The second mask layer 158 may be etched using the photoresist to have the opening patterns 160a, 160b and 160c. The photoresist may be removed during the etching process or by an additional aching process.

The dielectric capping layer 150 has a different etching selectively than the upper interlayer dielectric layer 154 and the lower interlayer dielectric layer 134, and may protect the underlying final gate stacks 140 and the gate spacer layers 118, in accordance with some embodiments. Therefore, the opening patterns 160a, 160b and 160c may have wider critical dimensions (CDs) in the X direction, thereby relaxing the process limit of the photolithography process.

The opening pattern 160a partially overlaps the nanostructures 109a, and the opening pattern 160b partially overlaps the nanostructures 109b, as shown in FIG. 5H-1, in accordance with some embodiments. That is, the extension lines of the opposite edges of the opening patterns 160a and 160b with respect to the X direction pass through the nanostructures 109a and 109b, in accordance with some embodiments.

FIGS. 5I-1 and 5I-2 are cross-sectional views of a semiconductor structure 100 after the formation of a third mask layer 162, in accordance with some embodiments.

A third mask layer 162 is formed over the second mask layer 158, as shown in FIGS. 5I-1 and 5I-2, in accordance with some embodiments. The third mask layer 162 covers the N-type well region NW1 and exposes the P-type well regions PW1 and PW2, in accordance with some embodiments. In some embodiments, the opening pattern 160b is filled with the third mask layer 162.

In some embodiments, the third mask layer 162 is a patterned photoresist layer formed by a photolithography process as described above. In alternative embodiments, the third mask layer 162 is a patterned hard mask layer, which is formed by depositing a dielectric material, forming a patterned photoresist over the dielectric material, and etching the dielectric material using the patterned photoresist.

FIGS. 5J-1 and 5J-2 are cross-sectional views of a semiconductor structure 100 after the formation of contact openings 164a and 164c, in accordance with some embodiments.

One or more etching processes are performed to etch away portions of the first mask layer 156, the upper interlayer dielectric layer 154, the dielectric capping layer 150, the contact etching stop layer 132, the lower interlayer dielectric layer 134 exposed from the opening patterns 160a and 160c, as shown in FIGS. 5J-1 and 5J-2, in accordance with some embodiments. The etching process may be an anisotropic etching process such as dry plasma etching. In the etching process, portions of the second mask layer 158 and the first mask layer 156 uncovered by the third mask layer 162 are also removed, in accordance with some embodiments.

The opening patterns 160a and 160c are transferred into the dielectric capping layer 150, the contact etching stop layer 132, the lower interlayer dielectric layer 134 to form a contact opening 164a to the source/drain features 124a and a contact opening 164c to the source/drain features 124d, as shown in FIGS. 5J-1 and 5J-2, in accordance with some embodiments.

The one or more etching processes include a step (such as an over-etching step) for recessing the source/drain features 124a and 124d, and thus the contact openings 164a and 164c extend into the bulk layer 130 of the source/drain features 124a and 124d by a distance, in accordance with some embodiments. In some embodiments, during the step for recessing the source/drain features, the etching chamber provides an RF bias/source power in a range from 600 watts (W) to about 800 W. In some embodiments, the step for recessing the source/drain features uses HBr, HCl, NF₃, and/or a mixture thereof as etchants and is performed under the temperature in a range from about 600° C. to about 800° C. and at about one atmosphere for a first time period in a range from about 5 seconds to about 100 seconds.

Afterward, the third mask layer 162 is removed using an etching process or an ashing process, thereby exposing the remainder of the second mask layer 158, in accordance with some embodiments.

FIGS. 5K-1 and 5K-2 are cross-sectional views of a semiconductor structure 100 after the formation of a fourth mask layer 166, in accordance with some embodiments.

A fourth mask layer 166 is formed to cover the P-type well regions PW1 and PW2 and exposes the N-type well region NW1, as shown in FIGS. 5K-1 and 5K-2, in accordance with some embodiments. In some embodiments, the contact openings 164a and 164c are filled with the fourth mask layer 166.

In some embodiments, the fourth mask layer 166 is a patterned photoresist layer formed by a photolithography process as described above. In alternative embodiments, the fourth mask layer 166 is a patterned hard mask layer, which is formed by depositing a dielectric material, forming a patterned photoresist over the dielectric material, and etching the dielectric material using the patterned photoresist.

FIGS. 5L-1 and 5L-2 are cross-sectional views of a semiconductor structure 100 after the formation of a contact opening 164b, in accordance with some embodiments.

One or more etching processes are performed to etch away portions of the first mask layer 156, the upper interlayer dielectric layer 154, the dielectric capping layer 150, the contact etching stop layer 132, the lower interlayer dielectric layer 134 exposed from the opening pattern 160b, as shown in FIGS. 5L-1 and 5L-2, in accordance with some embodiments. The etching process may be an anisotropic etching process such as dry plasma etching. In the etching process, remaining portions of the second mask layer 158 and the first mask layer 156 are also removed, in accordance with some embodiments.

The opening pattern 160b is transferred into the dielectric capping layer 150, the contact etching stop layer 132, the lower interlayer dielectric layer 134 to form a contact opening 164b to the source/drain feature 124b, as shown in FIGS. 5L-1 and 5L-2, in accordance with some embodiments.

The one or more etching processes include a step (such as an over-etching step) for recessing the bulk layer 130 of the source/drain feature 124b, and thus the contact opening 164b extends into the source/drain feature 124b by a distance, in accordance with some embodiments. In some embodiments, during the step for recessing the source/drain feature, the etching chamber provides an RF bias/source power in a range from 600 W to about 800 W. In some embodiments, the step for recessing the source/drain features uses HBr, HCl, NF₃, and/or a mixture thereof as etchants and is performed under the temperature in a range from about 600° C. to about 800° C. and at about one atmosphere for a second time period that is less than the first time period of recessing the source/drain features 124a and 124d. In some embodiments, the second time period is about 0.6 to about 0.8 of the first time period and is in a range from about 3 second to about 80 second.

Therefore, the recessing depths of the contact openings 164a and 164c in the source/drain features 124a and 124d are greater than the recessing depth of the contact opening 164b in the source/drain feature 124b, in accordance with some embodiments.

FIGS. 5M-1 and 5M-2 are cross-sectional views of a semiconductor structure 100 after the removal of the fourth mask layer 166, in accordance with some embodiments. The fourth mask layer 166 is removed using an etching process or an ashing process, in accordance with some embodiments.

By controlling the recessing depth of the contact opening, the contact area between the subsequently formed contact plug and the source/drain feature can be adjusted, thereby adjusting the performance (e.g., saturation current (Idsat)) of the nanostructure transistors.

The contact openings 164a and 164c in the P-type well regions PW1 and PW2 and the contact opening 164b in the N-type well region NW1 are formed separately, and thus the contact openings 164a and 164c and the contact opening 164b may be formed to have different recessing depths, in accordance with some embodiments.

As a result, by forming the contact openings 164a and 164c and the contact opening 164b separately, independent adjustment of the performances of the n-channel nanostructure transistors (e.g., the pull-down transistor PD-2 and the pass-gate transistor PG-1) and the p-channel nanostructure transistors (e.g., the pull-up transistor PU-2) may be achieved, which may in turn adjust the cell performance of the resulting SRAM devices, such as the write margin metric and/or the operation voltage (Vcc_min), in accordance with some embodiments.

FIG. 5M-3 is an enlarged view of the contact opening 164a and 164b shown in FIG. 5M-1, in accordance with some embodiments of the disclosure.

A portion of the contact opening 164a (or 164c) extending into the source/drain feature 124a (or 124d) has a first dimension D1 (the recessing depth) measured from the top surface of the source/drain feature 124a (or 124d) to the bottom of the contact opening 164a (or 164c), as shown in FIG. 5M-3, in accordance with some embodiments. In some embodiments, the first dimension D1 is in a range from about 5 nm to about 15 nm.

A portion of the contact opening 164b extending into the source/drain feature 124b has a second dimension D2 (the recessing depth) measured from the top surface of the source/drain feature 124b to the bottom of the contact opening 164b, in accordance with some embodiments. In some embodiments, the second dimension D2 is in a range from about 3 nm to about 12 nm.

In some embodiments, the second dimension D2 is less than the first dimension D1. In some embodiment, the ratio (D2/D1) of the second dimension D2 to the first dimension D1 is in a range from about 0.6 to about 0.8. If the ratio (D2/D1) is too large and/or the second dimension D2 is too large, the “alpha ratio” of the saturation current may increase, which may lead worse cell performance (e.g., increase in operation voltage) and/or poor write margin metric (e.g., lower operation speed). If the ratio (D2/D1) is too small and/or the first dimension D1 is too large, the nanostructures 109a and 109c may be damaged during the etching process for forming the contact openings 164a and 164c.

In some embodiments, the bottom end 164a1 of the contact opening 164a is located at a level between the bottom surface of the uppermost nano structure 109a1 and the top surface of the second uppermost nanostructure 109a2, as shown in FIG. 5M-3. In some embodiments, the bottom end 164b1 of the contact opening 164b is located at a level between the top surface and the bottom surface of the uppermost nanostructure 109b1, as shown in FIG. 5M-3.

FIGS. 5N-1 and 5N-2 are cross-sectional views of a semiconductor structure 100 after the formation of a glue layer 168, a barrier layer 170, a silicide layer 172 and a metal bulk layer 174, in accordance with some embodiments.

A glue layer 168 is conformally formed over the semiconductor structure 100 to partially fill the contact openings 164a-164c, as shown in FIGS. 5N-1 and 5N-2, in accordance with some embodiments. The glue layer 168 is used to improve adhesion between the subsequently formed metal bulk material and the dielectric material (e.g., the lower interlayer dielectric layer 134 and the contact etching stop layer 132).

The glue layer 168 may be made of electrically conductive material such as titanium (Ti), nickel (Ni), cobalt (Co), tungsten (W), tantalum nitride (TaN), titanium nitride (TiN), another suitable material, and/or a combination thereof. In some embodiments, the glue layer 168 is deposited using CVD, PVD, e-beam evaporation, ALD, electroplating (ECP), electroless deposition (ELD), another suitable method, or a combination thereof.

An etching back process is performed to remove a portion of the glue layer 168 formed over the upper interlayer dielectric layer 154 and partially remove a portion of the glue layer 168 formed along the dielectric capping layer 150, in accordance with some embodiments. The etching process may be an anisotropic etching process, e.g., dry plasma etching.

A barrier layer 170 is conformally formed over the glue layer 168 to partially fill the contact openings 164a-164c, as shown in FIGS. 5N-1 and 5N-2, in accordance with some embodiments. The barrier layer 170 is used to prevent the metal from the subsequently formed metal bulk material from diffusing into the dielectric material (e.g., the lower interlayer dielectric layer 134 and the contact etching stop layer 132).

The barrier layer may be made of electrically conductive material such as titanium nitride (TiN), tantalum nitride (TaN), cobalt tungsten (CoW), tantalum (Ta), titanium (Ti), another suitable material, and/or a combination thereof. In some embodiments, the barrier layer 170 is TiN layer and the glue layer 168 is Ti layer. In some embodiments, the barrier layer 170 is deposited using CVD, PVD, e-beam evaporation, ALD, ECP, ELD, another suitable method, or a combination thereof.

An etching back process is performed to remove a portion of the barrier layer 170 formed over the upper interlayer dielectric layer 154 and a portion of the barrier layer 170 formed along the bottom of the contact openings 164a-164c, in accordance with some embodiments. The etching process may be an anisotropic etching process, e.g., dry plasma etching.

An anneal process is performed on the semiconductor structure 100 to form a silicide layer 172, as shown in FIG. 5N-1 and 5N-2, in accordance with some embodiments. During the anneal process, metal material from the glue layer 168 react with semiconductor material from the source/drain features 124a, 124b and 124d so that portions of the glue layer 170 in contact with the source/drain features 124a, 124b and 124d are transformed into the silicide layers 172, in accordance with some embodiments. In some embodiments, the silicide layer 172 is TiSi, CoSi, NiSi, WSi, and/or another suitable silicide layer. In some embodiments, the anneal process includes one or more rapid thermal anneal (RTA) processes.

A metal bulk layer 174 is formed over the semiconductor structure 100 to overfill remainders of the contact openings 164a-164c, as shown in FIGS. 5N-1 and 5N-2, in accordance with some embodiments. In some embodiments, the metal bulk layer 174 is made of electrically conductive materials with low resistance and good gap-fill ability, for example, cobalt (Co), nickel (Ni), tungsten (W), titanium (Ti), tantalum (Ta), copper (Cu), aluminum (Al), ruthenium (Ru), molybdenum (Mo), another suitable metal material, and/or a combination thereof. In some embodiments, the metal bulk layer 174 is deposited using CVD, PVD, e-beam evaporation, ALD, ECP, ELD, another suitable method, or a combination thereof.

FIGS. 5O-1 and 5O-2 are cross-sectional views of a semiconductor structure 100 after the formation of contact plugs 178a, 178b and 178c, in accordance with some embodiments.

A planarization process is performed on the metal bulk layer 174, the barrier layer 170, the glue layer 168 and the upper interlayer dielectric layer 154 until the dielectric capping layer 150 and the lower interlayer dielectric layer 134 are exposed, as shown in FIGS. 5O-1 and 5O-2, in accordance with some embodiments. The planarization may be CMP, etching back process, or a combination thereof. The remaining portions of the glue layer 168, the barrier layer 170 and the metal bulk layer 174 and the silicide layer 172 combine to form a contact plug 178a to the source/drain feature 124a, a contact plug 178b to the source/drain feature 124b, and a contact plug 178c to the source/drain feature 124d, in accordance with some embodiments.

Portions of the contact plugs 178a, 178b and 178c are embedded in the source/drain features 124a, 124b and 124d, in accordance with some embodiments. The portion of the contact plug 178a (and 178c) embedded in the source/drain features 124a (and 124d) extends to a deeper position than the position to which the portion of the contact plug 178b embedded in the source/drain features 124b extends, and thus the contact area between the contact plug 178a and the source/drain feature 124a (and the contact area between the contact plug 178c and the source/drain feature 124d) is greater than the contact area between the contact plug 178b and the source/drain feature 124b, in accordance with some embodiments.

Greater contact areas may suppress the current crowding effect, thereby increasing the saturation current of the nanostructure transistors. As a result, by forming the contact plugs 178a and 178c with relatively great embedded portions and the contact plug 178b with a relatively small embedded portion, the n-channel nanostructure transistors (e.g., the pull-down transistor PD-2 and the pass-gate transistor PG-1) may have relatively strong performance while the p-channel nanostructure transistors (e.g., the pull-up transistor PU-2) may have relatively weak performance, in accordance with some embodiments. Therefore, the alpha ratio of the saturation current (PU Idsat/PG Idsat) may decrease, which may enhance cell performance (e.g., decrease in operation voltage) and/or expand write margin metric (e.g., increase in operation speed).

FIG. 5O-3 is an enlarged view of the contact plugs 178a and 178b shown in FIG. 5M-1, in accordance with some embodiments of the disclosure.

A portion of the contact plug 178a (or 178c) embedded in the source/drain feature 124a (or 124d) has a first dimension D1 measured from the top surface of the source/drain feature 124a (or 124d) to the bottom of the contact plug 178a (or 178c), as shown in FIG. 5O-3, in accordance with some embodiments. In some embodiments, the first dimension D1 is in a range from about 5 nm to about 15 nm.

A portion of the contact plug 178b embedded in the source/drain feature 124b has a second dimension D2 measured from the top surface of the source/drain feature 124b to the bottom of the contact plug 178b, in accordance with some embodiments. In some embodiments, the second dimension D2 is in a range from about 3 nm to about 15 nm.

In some embodiments, the second dimension D2 is less than the first dimension D1. In some embodiment, the ratio (D2/D1) of the second dimension D2 to the first dimension D1 is in a range from about 0.6 to about 0.8. If the ratio (D2/D1) is too large and/or the second dimension D2 is too large, the “alpha ratio” of the saturation current may increase, which may lead worse cell performance (e.g., increase in operation voltage) and/or poor write margin metric (e.g., lower operation speed). If the ratio (D2/D1) is too small and/or the first dimension D1 is too large, the nanostructures 109a and 109c may be damaged during the etching process for forming the contact openings 164a and 164c.

In some embodiments, portions of the contact plugs 178a, 178b and 178c outside the source/drain features 124a, 124b or 124d has a third dimension D3 measured from the top surface of the source/drain features 124a, 124b and 124d to the top surface of the contact plugs 178a, 178b and 178c, as shown in FIG. 5O-3, in accordance with some embodiments. In some embodiments, the third dimension D3 is in a range from about 50 nm to about 150 nm. In some embodiments, the thickness (D3+D1) of the contact plugs 178a and 178c in the Z direction is greater than the thickness (D3+D2) of the contact plug 178b in the Z direction.

In some embodiments, the top surface of the contact plugs 178a, 178b and 178c has a fourth dimension D4 measured in the X direction, as shown in FIG. 5O-3, in accordance with some embodiments. In some embodiments, the fourth dimension D4 is in a range from about 50 nm to about 150 nm.

In some embodiments, the contact plugs 178a, 178b and 178c has a fifth dimension D5 at the top surface of the source/drain features 124a, 124b and 124d, measured in the X direction, as shown in FIG. 5O-3, in accordance with some embodiments. In some embodiments, the fifth dimension D5 is in a range from about 50 nm to about 100 nm.

In some embodiments, the bottom end 178a1 of the contact plug 178a is located at a level between the bottom surface of the uppermost nanostructure 109a1 and the top surface of the second uppermost nanostructure 109a2, as shown in FIG. 5O-1. In some embodiments, the bottom end 178b1 of the contact opening 178b is located at a level between the top surface and the bottom surface of the uppermost nanostructure 109b1, as shown in FIG. 5O-1.

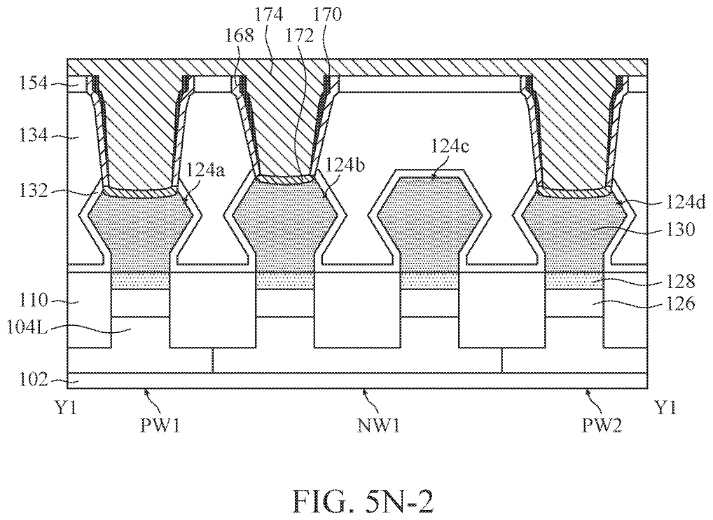

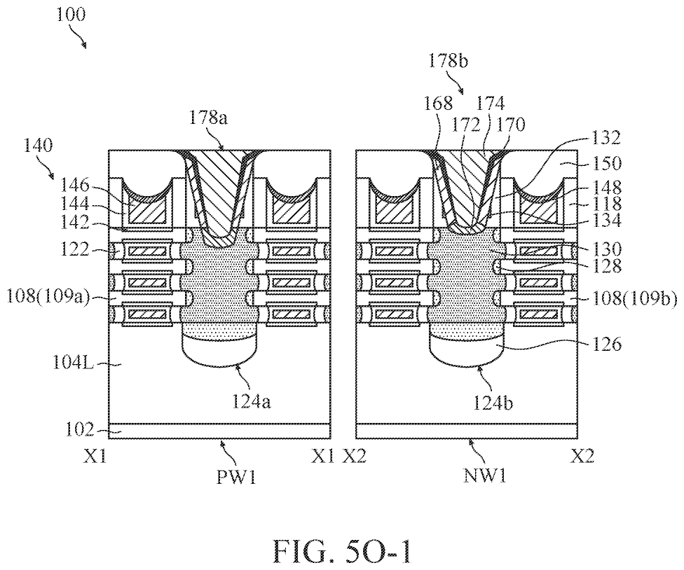

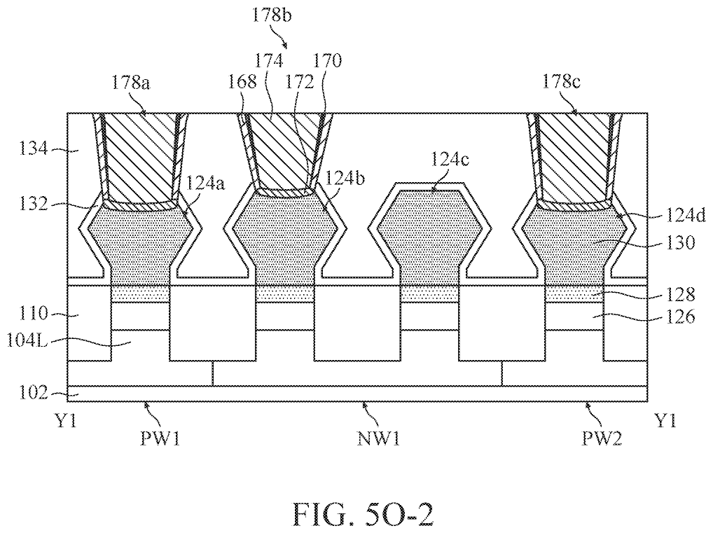

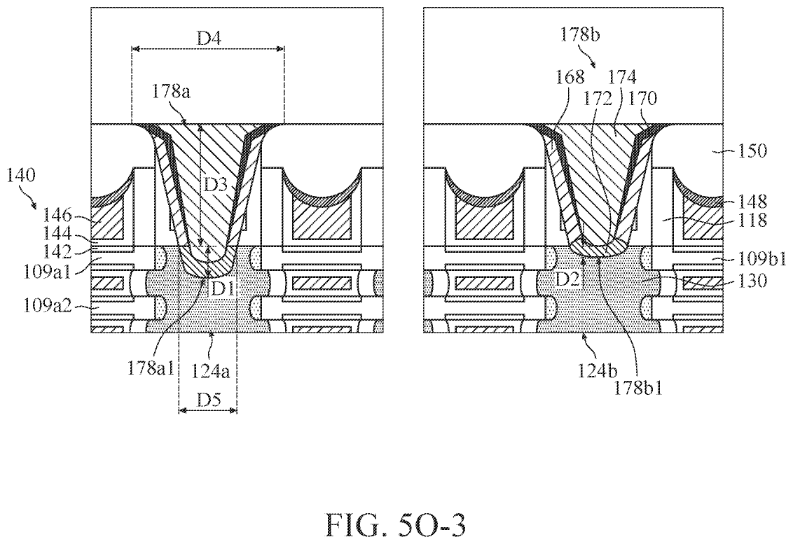

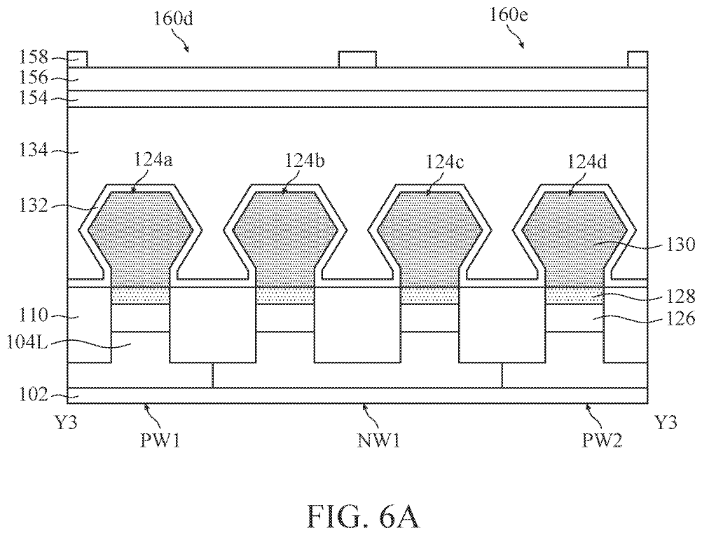

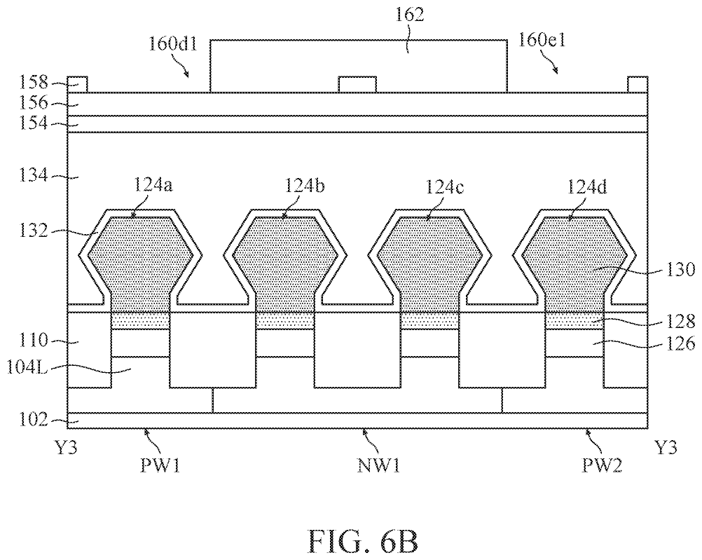

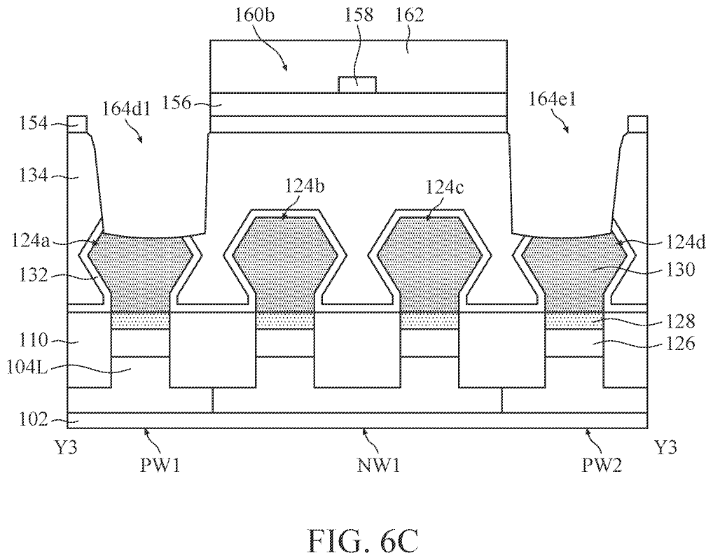

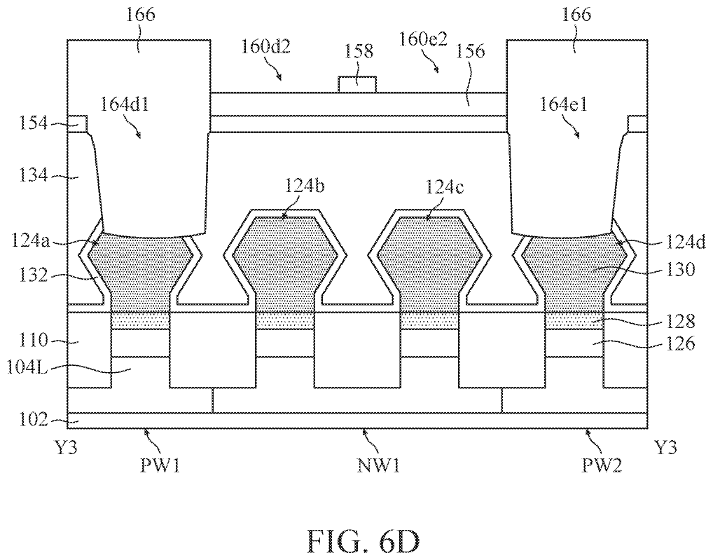

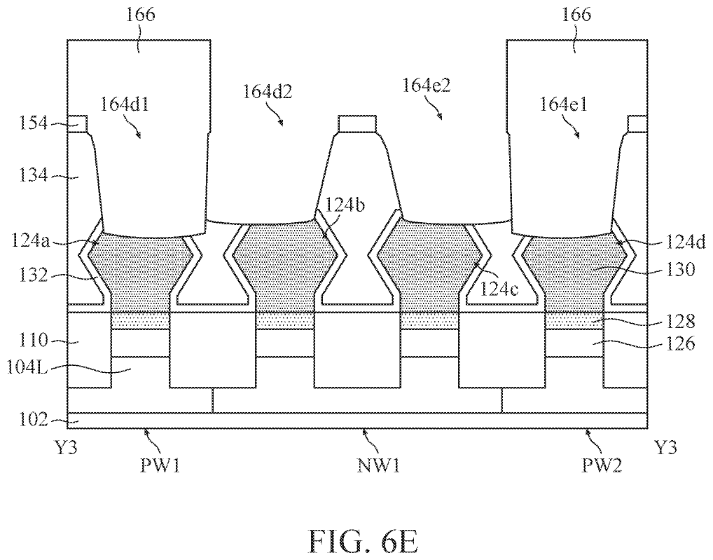

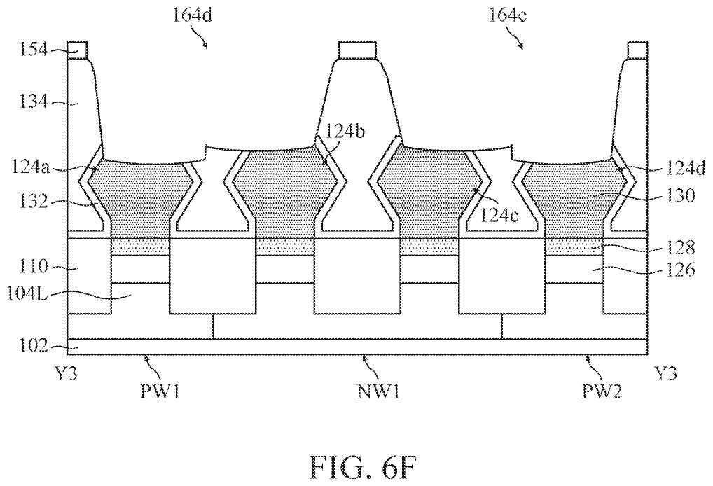

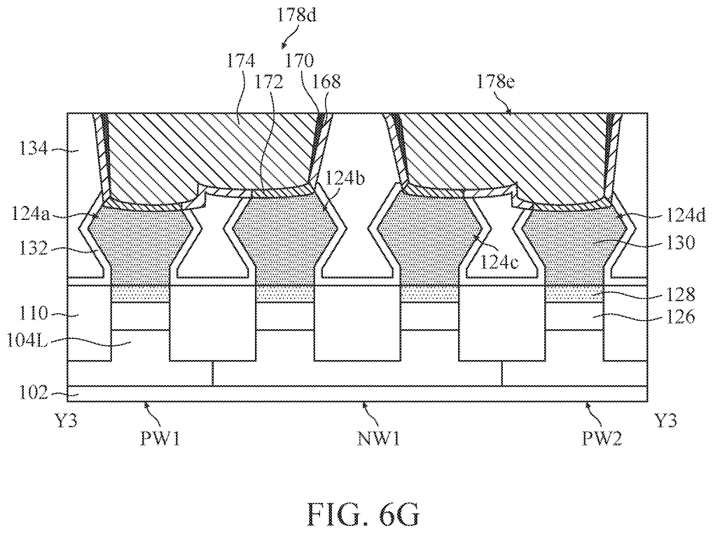

FIGS. 6A through 6G are cross-sectional views of the semiconductor structure 100 corresponding to cross-section Y3-Y3 shown in FIG. 4 to illustrate the formation of contact plugs 178d and 178e to the source/drain features, in accordance with some embodiments. Elements or layers in FIGS. 6A through 6G that are the same or similar are denoted by reference numerals like those in FIGS. 5A-1 through 5O-3 as they have the same meaning, and the description thereof will not be repeated for the sake of brevity.

In some embodiments, the contact plugs 178d and 178e shown in FIG. 6G are the same as the contact plugs 178d and 178e shown in FIG. 3. In some embodiments, each of the contact plugs 178d and 178e is shared by two source/drain features 124 and includes a first portion in the P-type well region PW1 or PW2 and a second portion in the N-type well region NW1. The first portion of the contact plug in the P-type well region has a different dimension than the second portion of the contact plug in the N-type well region, in accordance with some embodiments.

FIG. 6A is a cross-sectional view of a semiconductor structure 100 after the formation of an upper interlayer dielectric layer 154 and mask layers 156 and 158, in accordance with some embodiments. A patterning process is performed on the second mask layer 158 to form opening patterns 160d and 160e, as shown in FIG. 6A, in accordance with some embodiments. The opening pattern 160d corresponds to and overlaps the source/drain features 124a and 124b, and the opening pattern 160e corresponds to and overlaps the source/drain features 124c and 124d, in accordance with some embodiments.

FIG. 6B is a cross-sectional view of a semiconductor structure 100 after the formation of a third mask layer 162, in accordance with some embodiments. The third mask layer 162 covers the N-type well region NW1 and exposes the P-type well regions PW1 and PW2, as shown in FIG. 6B, in accordance with some embodiments. In some embodiments, the opening pattern 160d is partially filled with the third mask layer 162, and a remaining portion of the opening pattern 160d in the P-type well region PW1 is referred to as an opening pattern 160d1. In some embodiments, the opening pattern 160e is partially filled with the third mask layer 162, and a remaining portion of the opening pattern 160e in the P-type well region PW2 is referred to as an opening pattern 160e1.

FIG. 6C is a cross-sectional view of a semiconductor structure 100 after the formation of a first portion 164d1 of a contact opening 164d and a first portion 164e1 of a contact opening 164e, in accordance with some embodiments. One or more etching processes are performed to etch away portions of the first mask layer 156, the upper interlayer dielectric layer 154, the dielectric capping layer 150, the contact etching stop layer 132, the lower interlayer dielectric layer 134 exposed from the opening patterns 160d1 and 160e1, as shown in FIG. 6C, in accordance with some embodiments.

The opening patterns 160d1 and 160e1 are transferred into the dielectric capping layer 150, the contact etching stop layer 132, the lower interlayer dielectric layer 134 to form a first portion 164d1 of a contact opening 164d and a first portion 164e1 of a contact opening 164e, in accordance with some embodiments. The first portion 164d1 of the contact opening 164d extends to the source/drain feature 124a, and the first portion 164e1 of the contact opening 164e extends to the source/drain feature 124d, in accordance with some embodiments.

Afterward, the third mask layer 162 is removed using an etching process or an ashing process, thereby exposing the remainder of the second mask layer 158, in accordance with some embodiments.

FIG. 6D is a cross-sectional view of a semiconductor structure 100 after the formation of a fourth mask layer 166, in accordance with some embodiments. The fourth mask layer 166 covers the P-type well regions PW1 and PW2 and exposes the N-type well region NW1, as shown in FIG. 6D, in accordance with some embodiments. In some embodiments, a remaining portion of the opening pattern 160d in the N-type well region NW1 is referred to as an opening pattern 160d2. In some embodiments, a remaining portion of the opening pattern 160e in N-type well region NW1 is referred to as an opening pattern 160e2. In some embodiments, the first portion 164d1 of the contact opening 164d and the first portion 164d1 of the contact opening 164e are filled with the fourth mask layer 166.

FIG. 6E is a cross-sectional view of a semiconductor structure 100 after the formation of a second portion 164d2 of the contact opening 164d and a second portion 164e2 of the contact opening 164e, in accordance with some embodiments. One or more etching processes are performed to etch away portions of the first mask layer 156, the upper interlayer dielectric layer 154, the dielectric capping layer 150, the contact etching stop layer 132, the lower interlayer dielectric layer 134 exposed from the opening patterns 160d2 and 160e2, as shown in FIG. 6E, in accordance with some embodiments.

The opening patterns 160d2 and 160e2 are transferred into the dielectric capping layer 150, the contact etching stop layer 132, the lower interlayer dielectric layer 134 to form a second portion 164d2 of the contact opening 164d and a second portion 164e2 of the contact opening 164e, in accordance with some embodiments. The second portion 164d2 of the contact opening 164d extends to the source/drain feature 124b, and the second portion 164e2 of the contact opening 164e extends to the source/drain feature 124c, in accordance with some embodiments.

The recessing depth of the first portion 164d1 of the contact opening 164d in the source/drain feature 124a is greater than the recessing depth of the second portion 164d2 of the contact opening 164d in the source/drain feature 124b, in accordance with some embodiments. The recessing depth of the first portion 164e1 of the contact opening 164e in the source/drain feature 124d is greater than the recessing depth of the second portion 164e2 of the contact opening 164e in the source/drain feature 124c, in accordance with some embodiments.

FIG. 6F is a cross-sectional view of a semiconductor structure 100 after the removal of the fourth mask layer 166, in accordance with some embodiments. The first portion 164d1 and the second portion 164d2 are connected to each other and combined to form the contact opening 164d, in accordance with some embodiments. The first portion 164e1 and the second portion 164e2 are connected to each other and combined to form the contact opening 164e, in accordance with some embodiments.

FIG. 6G is a cross-sectional view of a semiconductor structure 100 after the formation of contact plugs 178d and 178e, in accordance with some embodiments. A glue layer 168 is conformally formed over the semiconductor structure 100, and then an etching back process is performed on the glue layer 168, in accordance with some embodiments. A barrier layer 170 is conformally formed over the glue layer 168, and then an etching back process is performed on the barrier layer 170, in accordance with some embodiments.

An anneal process is performed so that portions of the glue layer 168 in contact with the source/drain features 124a-124d are transformed into the silicide layers 172, in accordance with some embodiments. A metal bulk layer 174 is formed over the semiconductor structure 100 to overfill remainders of the contact openings 164d and 164e, and then a planarization process is performed until the dielectric capping layer 150 and the lower interlayer dielectric layer 134 are exposed, in accordance with some embodiments.

The remaining portions of the glue layer 168, the barrier layer 170, and the metal bulk layer 174 and the silicide layer 172 combine to form a contact plug 178d to the source/drain features 124a and 124b and a contact plug 178e to the source/drain features 124c and 124d, in accordance with some embodiments.

A first portion of the contact plug 178d embedded in the source/drain features 124a extends to a deeper position than the position to which a second portion of the contact plug 178d embedded in the source/drain features 124b extends, and thus the contact area between the contact plug 178d and the source/drain feature 124a is greater than the contact area between the contact plug 178d and the source/drain feature 124b, in accordance with some embodiments.

Similarly, a first portion of the contact plug 178e embedded in the source/drain features 124d extends to a deeper position than the position to which a second portion of the contact plug 178e embedded in the source/drain features 124c extends, and thus the contact area between the contact plug 178e and the source/drain feature 124d is greater than the contact area between the contact plug 178e and the source/drain feature 124c, in accordance with some embodiments.

As a result, the n-channel nanostructure transistors (e.g., the pull-down transistor PD-2 and the pass-gate transistor PG-1) may have relatively strong performance while the p-channel nanostructure transistors (e.g., the pull-up transistor PU-2) may have relatively weak performance, in accordance with some embodiments. Therefore, the alpha ratio of the saturation current (PU Idsat/PG Idsat) may decrease, which may enhance cell performance (e.g., decrease in operation voltage) and/or expand write margin metric (e.g., increase in operation speed).

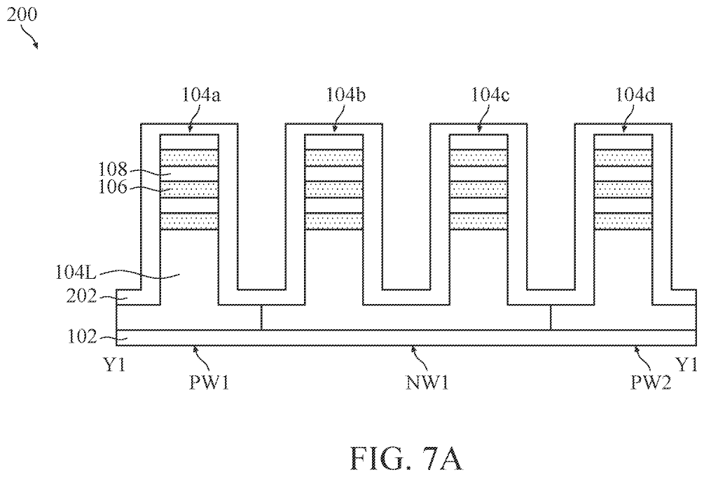

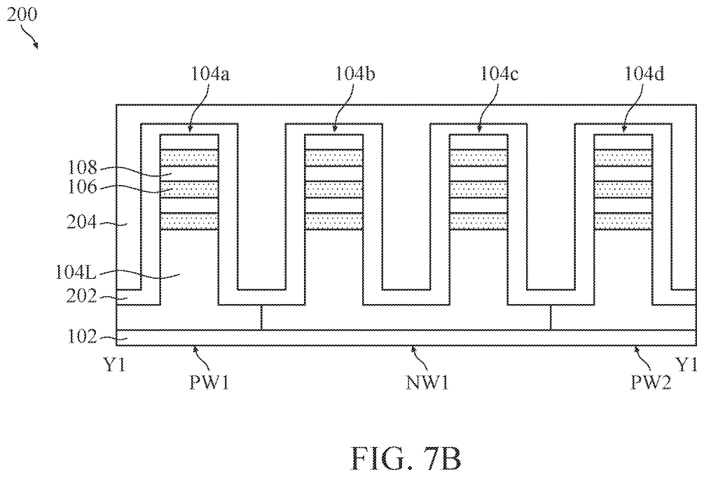

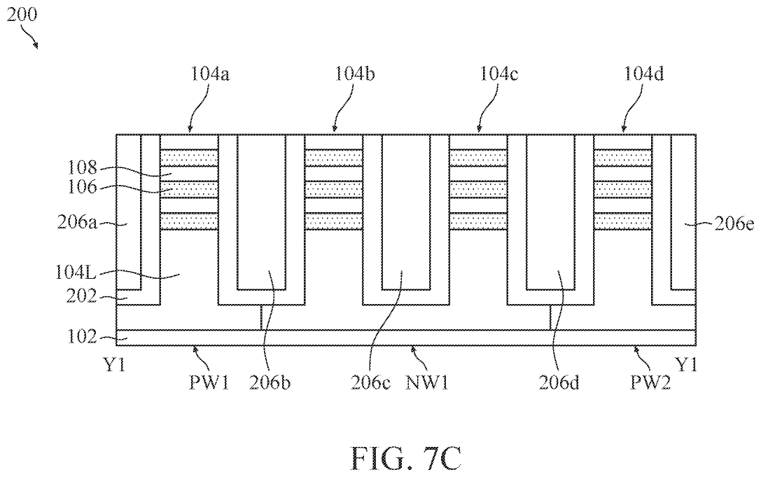

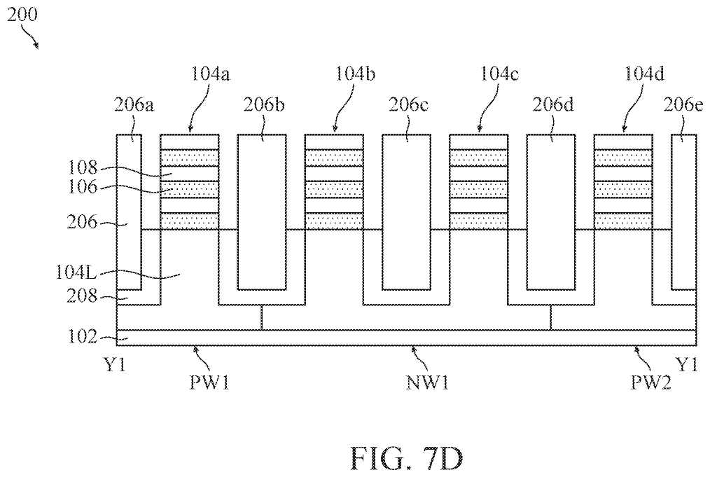

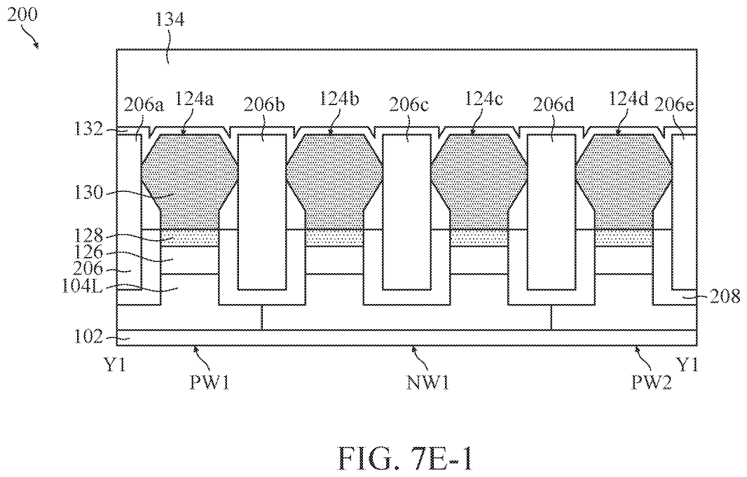

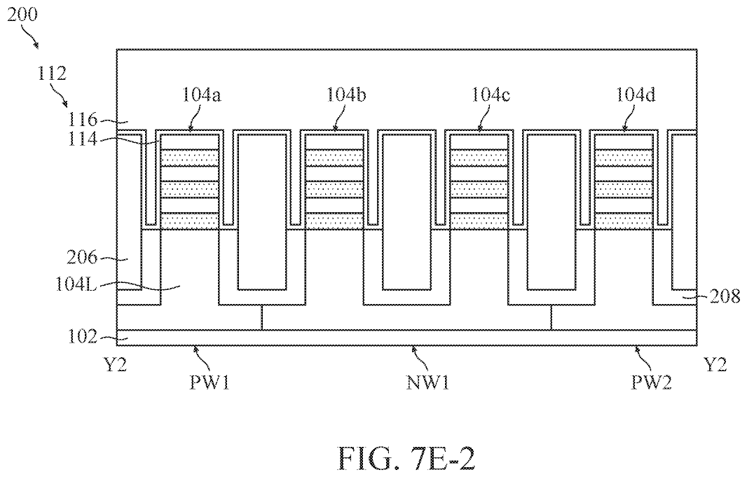

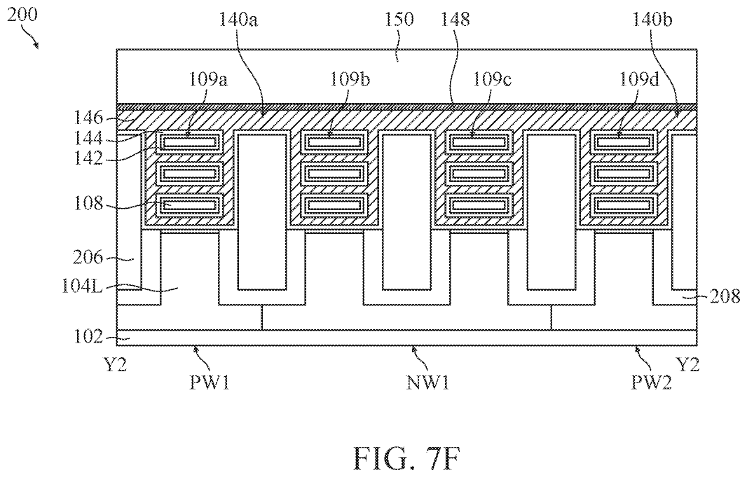

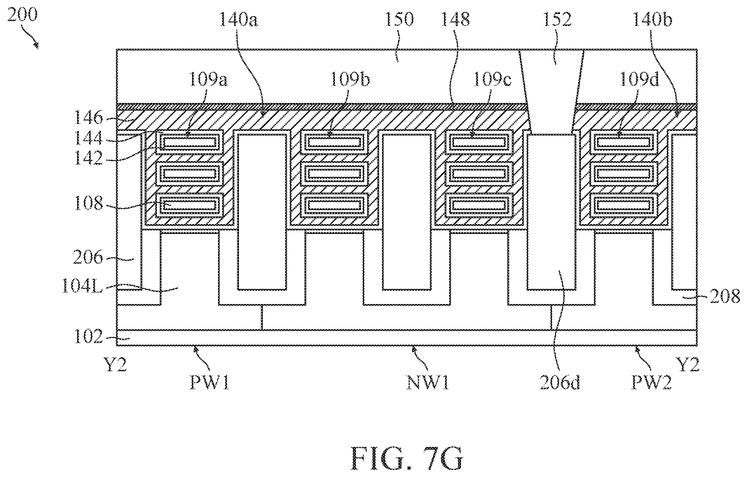

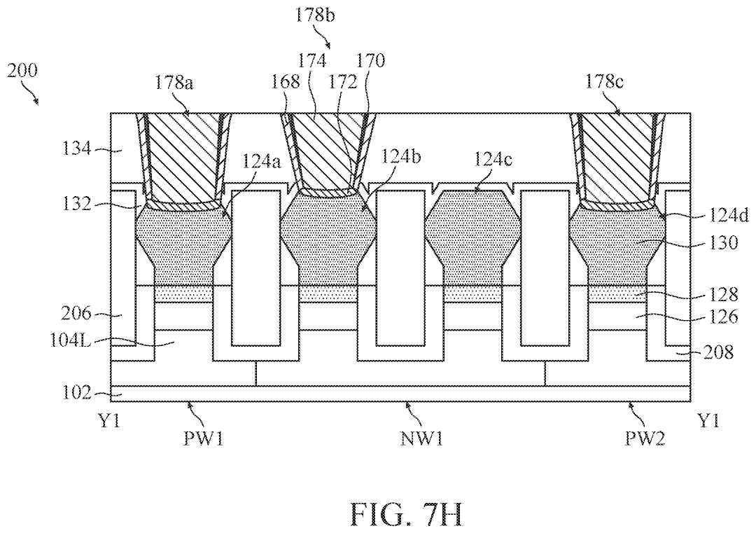

FIGS. 7A through 7H are cross-sectional views illustrating the formation of a semiconductor structure 200 of an SRAM cell at various intermediate stages, in which FIGS. 7A, 7B, 7C, 7D, 7E-1 and 7H correspond to cross-section Y1-Y1 shown in FIG. 4, and FIGS. 7E-2, 7F and 7G correspond to cross-section Y2-Y2 shown in FIG. 4, in accordance with some embodiments.

In some embodiments, the semiconductor structure 200 is used to form the SRAM cell 10_1 shown in FIG. 3. Elements or layers in FIGS. 7A through 7H that are the same or similar are denoted by reference numerals like those in FIGS. 5A-1 through 5O-3 as they have the same meaning, and the description thereof will not be repeated for the sake of brevity. The embodiments of FIGS. 7A through 7H are similar to the embodiments shown in FIGS. 5A-1 through 5O-3 except that dielectric fin structures 206 are formed between the fin structures 104.

FIG. 7A is a cross-sectional view of a semiconductor structure 200 after the formation of an isolation material 202, in accordance with some embodiments.

After the fin structures 104a-104d are formed, an insulating material 202 is conformally deposited over the semiconductor structure 200 to partially fill the trenches between the fin structures 104a-104d, as shown in FIG. 7A, in accordance with some embodiments.

In some embodiments, the insulating material 202 includes silicon oxide, silicon nitride, silicon oxynitride (SiON), another suitable insulating material, and/or a combination thereof. In some embodiments, the insulating material 202 is deposited using CVD (such as LPCVD, PECVD, or HDP-CVD, HARP, FCVD); ALD; another suitable method, and/or a combination thereof.

FIG. 7B is a cross-sectional view of a semiconductor structure 200 after the formation of a dielectric material 204, in accordance with some embodiments.

A dielectric material 204 is deposited over the insulating material 202 to overfill the remaining portions of the trenches, as shown in FIG. 7B, in accordance with some embodiments. In some embodiments, the dielectric material 204 includes silicon nitride (SiN) silicon carbon nitride (SiCN), silicon oxynitride (SiON), silicon carbon oxynitride SiCON, hafnium oxide (HfO₂), lanthanum oxide (La₂O₃), aluminum oxide (Al₂O₃), zirconium oxide (ZrO₂), another suitable insulating material, multilayers thereof, and/or a combination thereof.

In some embodiments, the dielectric material 204 and the insulating material 202 are made of different materials and have a great difference in etching selectivity. In some embodiments, the dielectric material 204 is deposited using CVD such as LPCVD, PECVD, HDP-CVD, HARP, FCVD, ALD, another suitable technique, and/or a combination thereof.

FIG. 7C is a cross-sectional view of a semiconductor structure 200 after a planarization process, in accordance with some embodiments.

A planarization process is performed to remove portions of the dielectric material 204 and the insulating material 202 formed above the fin structures 104a-104d until the upper surfaces of the fin structures 104a-104d are exposed. In some embodiments, the planarization process is an etching-back process or a CMP process. The remainder of the dielectric material 204 forms dielectric fin structures 206, in accordance with some embodiments of the disclosure.

The fin structure 104a is formed between a dielectric fin structure 206a and a dielectric fin structure 206b, the fin structure 104b is formed between a dielectric fin structure 206b and a dielectric fin structure 206c, the fin structure 104c is formed between a dielectric fin structure 206c and a dielectric fin structure 206d, and the fin structure 104d is formed between a dielectric fin structure 206d and a dielectric fin structure 206e, in accordance with some embodiments.

The dielectric fin structure 206a is located within the P-type well region PW1, the dielectric fin structure 206c is located within the N-type well region NW1, and the dielectric fin structure 206e is located within the P-type well region PW2, in accordance with some embodiments. The dielectric fin structure 206b is located at the boundary between the P-type well region PW1 and the N-type well region NW1, and the dielectric fin structure 206d is located at the boundary between the N-type well region NW1 and the P-type well region PW2, in accordance with some embodiments.

In some embodiments, the dielectric fin structures 206a-206e extend in the X direction. That is, the dielectric fin structures 206a-206e have longitudinal axes parallel to the X direction and substantially parallel to the fin structures 104a-104d, in accordance with some embodiments. In some embodiments, the dielectric fin structures 206 are also referred to as hybrid fin structures and configured as a portion for cutting a gate stack. The fin structures 104a-104d may also referred to as semiconductor fin structures.

FIG. 7D is a cross-sectional view of a semiconductor structure 200 after an etching process, in accordance with some embodiments.

The insulating material 202 is recessed using an etch process (such as dry plasma etching and/or wet chemical etching) until the upper fin elements of the fin structures 104a-104d are exposed, in accordance with some embodiments. The remainder of the insulating material 202 forms an isolation structure 208, in accordance with some embodiments of the disclosure.

The isolation structure 208 surrounds lower fin elements 104L and lower portions of the dielectric fin structures 206, in accordance with some embodiments. A portion of the isolation structure 208 extends below the dielectric fin structures 206, in accordance with some embodiments. The isolation structure 208 is configured to electrically isolate active regions (e.g., the fin structures 104a-104d) of the semiconductor structure 200 and is also referred to as STI feature, in accordance with some embodiments.

FIGS. 7E-1 and 7E-2 are cross-sectional views of a semiconductor structure 200 after the formation of a lower interlayer dielectric layer 134, in accordance with some embodiments.

The steps described above with respect to FIGS. 5B-1 through 5C-2 are performed, thereby forming the dummy gate structures 112, the inner spacer layers 122, the source/drain features 124, the contact etching stop layer 132, and the lower interlayer dielectric layer 134, as shown in FIGS. 7E-1 and 7E-2, in accordance with some embodiments.

In some embodiments, the source/drain features 124 are in contact with the sidewalls of the dielectric fin structures 206. In some embodiments, the dielectric fin structures 206 confine the lateral growth of the source/drain features 124, and thus the source/drain features 124 have narrower widths, thereby decreasing parasitic capacitance between the source/drain feature 124 and the metal gate electrode layer 146, in accordance with some embodiments.

In addition, as the feature sizes continue to decrease, the adjacent source/drain features of different transistors may be connected during the epitaxial process, which may cause undesirable bridge problem. In some embodiments, the dielectric fin structures 206 may be used to handle the bridge concern of the source/drain features. Therefore, the undesirable bridge problem can be prevented while the sizes of the source/drain features 124 may reach their maximum values, which may reduce the contact resistance between the source/drain feature and the contact plug.

FIG. 7F is a cross-sectional view of a semiconductor structure 200 after the formation of dielectric capping layers 150, in accordance with some embodiments.

The steps described above with respect to FIGS. 5D-1 through 5F-2 are performed, thereby forming the final gate stacks 140, the metal capping layers 148 and the dielectric capping layers 150, as shown in FIG. 7F, in accordance with some embodiments.

FIG. 7G is a cross-sectional view of a semiconductor structure 200 after the formation of a gate isolation structure 152, in accordance with some embodiments.

A gate isolation structure 152 is formed through the dielectric capping layer 150, the metal capping layer 148 and the final gate stack 140 and lands on the dielectric fin structure 206d, as shown in FIG. 7G, in accordance with some embodiments.

FIG. 7H is a cross-sectional view of a semiconductor structure 200 after the formation of contact plugs 178a, 178b and 178c, in accordance with some embodiments.

The steps described above with respect to FIGS. 5H-1 through 5O-3 are performed, thereby forming the contact plugs 178a, 178b and 178c, as shown in FIG. 7H, in accordance with some embodiments.

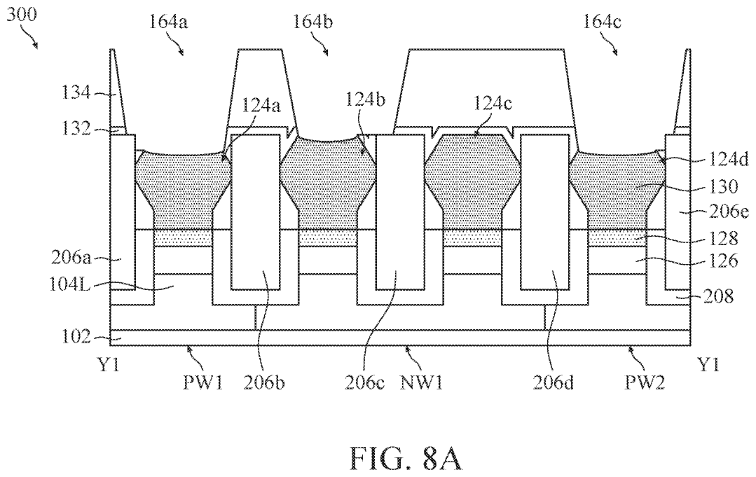

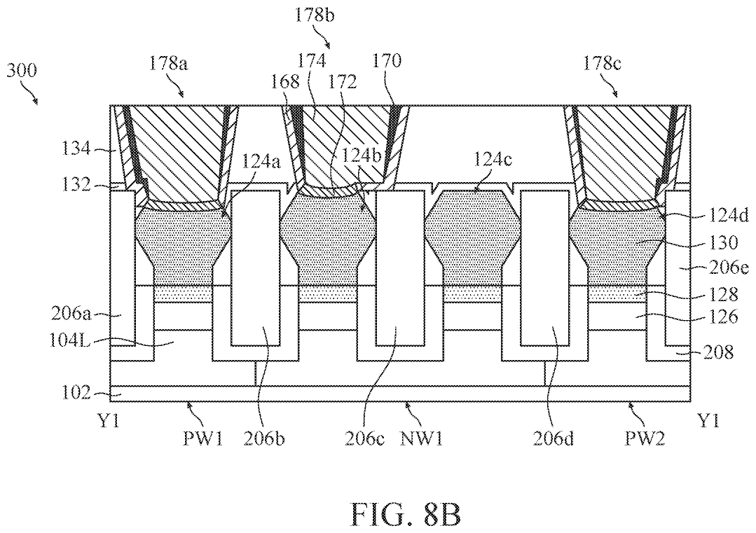

FIGS. 8A and 8B are cross-sectional views illustrating the formation of a semiconductor structure 300 of an SRAM cell at various intermediate stages, in which FIGS. 8A and 8B correspond to cross-section Y1-Y1 shown in FIG. 4, in accordance with some embodiments of the disclosure. In some embodiments, the semiconductor structure 300 is used to form the SRAM cell 10_1 shown in FIG. 3. The embodiments of FIGS. 8A and 8B are similar to the embodiments shown in FIGS. 7A through 7H except that contact plugs 178 partially cover the dielectric fin structures 206.

FIG. 8A is a cross-sectional view of a semiconductor structure 300 after the formation of contact opening 164a-164c, in accordance with some embodiments. In some embodiments, the contact opening 164a partially exposes the dielectric fin structure 206a, the contact opening 164b partially exposes the dielectric fin structure 206c, and the contact opening 164c partially exposes the dielectric fin structure 206e, as shown in FIG. 8A.

The dielectric fin structures 206 have a different etching selectively than the lower interlayer dielectric layer 134, and remain substantially unetched during the etching process for forming the contact openings 164a and 164c and the etching process for forming the contact opening 164b, in accordance with some embodiments. Therefore, the opening patterns 160a and 160b and 160c of the second mask layer 158 may have wider critical dimensions (CDs) in the Y direction, thereby relaxing the process limit of the photolithography process.

FIG. 8B is a cross-sectional view of a semiconductor structure 300 after the formation of contact plugs 178a, 178b and 178c, in accordance with some embodiments.

The steps described above with respect to FIGS. 5N-1 through 5O-3 are performed, thereby forming the contact plugs 178a, 178b and 178c, as shown in FIG. 8B, in accordance with some embodiments. In some embodiments, the contact plug 178a partially covers the dielectric fin structure 206a, the contact plug 178b partially covers the dielectric fin structure 206c, and the contact plug 178c partially covers the dielectric fin structure 206e, as shown in FIG. 8B.

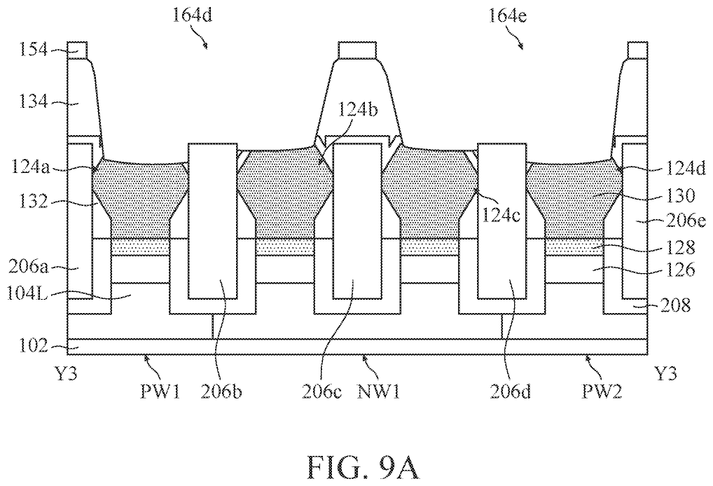

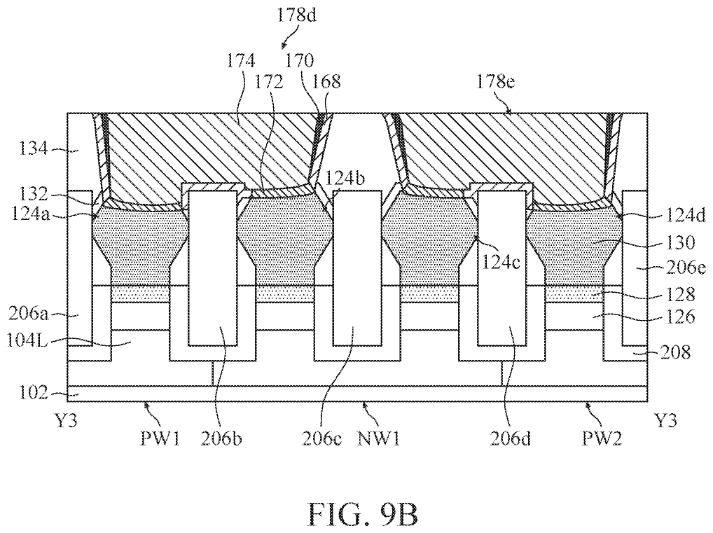

FIGS. 9A and 9B are cross-sectional views of the semiconductor structure 200 corresponding to cross-section Y3-Y3 shown in FIG. 4 to illustrate the formation of contact plugs 178d and 178e to the source/drain features, in accordance with some embodiments. Elements or layers in FIGS. 9A and 9B that are the same or similar are denoted by reference numerals like those in FIGS. 7A through 7H as they have the same meaning, and the description thereof will not be repeated for the sake of brevity.

FIG. 9A is a cross-sectional view of a semiconductor structure 200 after the formation of contact openings 164d and 164e, in accordance with some embodiments.

After the gate isolation structure 152 is formed, the steps described above with respect to FIGS. 6A through 6F are performed on the semiconductor structure 200 of FIG. 7G, thereby forming the contact opening 164d and 164e, as shown in FIG. 9A, in accordance with some embodiments. In some embodiments, the contact opening 164d exposes the dielectric fin structure 206b, and the contact opening 164e partially exposes the dielectric fin structure 206d, as shown in FIG. 9A.

FIG. 9B is a cross-sectional view of a semiconductor structure 300 after the formation of contact plugs 178d and 178e, in accordance with some embodiments.

The steps described above with respect to FIGS. 5N-1 through 5O-3 are performed, thereby forming the contact plugs 178d and 178e, as shown in FIG. 9B, in accordance with some embodiments.

A first portion of the contact plug 178d embedded in the source/drain features 124a extends to a deeper position than the position to which a second portion of the contact plug 178d embedded in the source/drain features 124b extends, and a first portion of the contact plug 178e embedded in the source/drain features 124d extends to a deeper position than the position to which a second portion of the contact plug 178e embedded in the source/drain features 124c extends, in accordance with some embodiments.

As a result, the n-channel nanostructure transistors (e.g., the pull-down transistor PD-2 and the pass-gate transistor PG-1) may have relatively strong performance while the p-channel nanostructure transistors (e.g., the pull-up transistor PU-2) may have relatively weak performance, in accordance with some embodiments. Therefore, the alpha ratio of the saturation current (PU Idsat/PG Idsat) may decrease, which may enhance cell performance (e.g., decrease in operation voltage) and/or expand write margin metric (e.g., increase in operation speed).

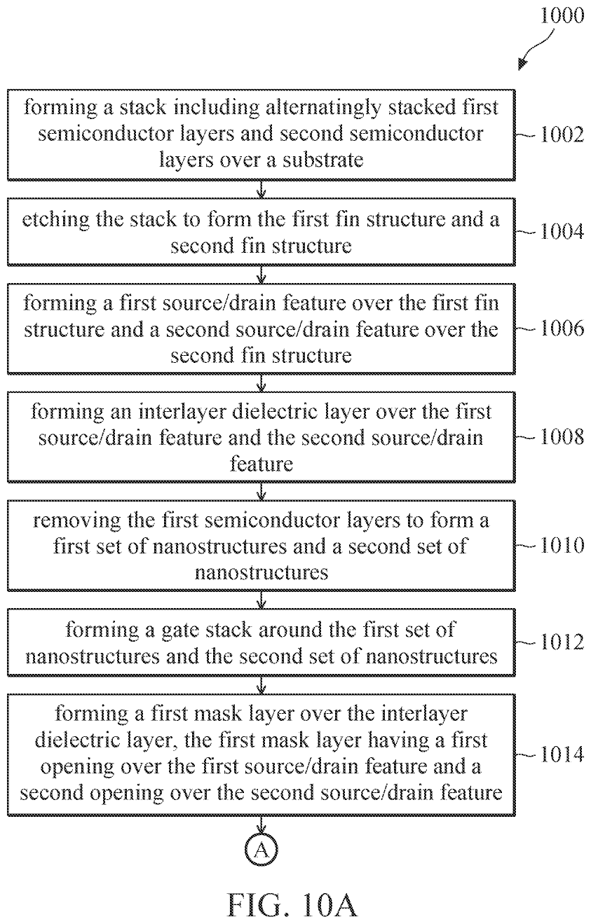

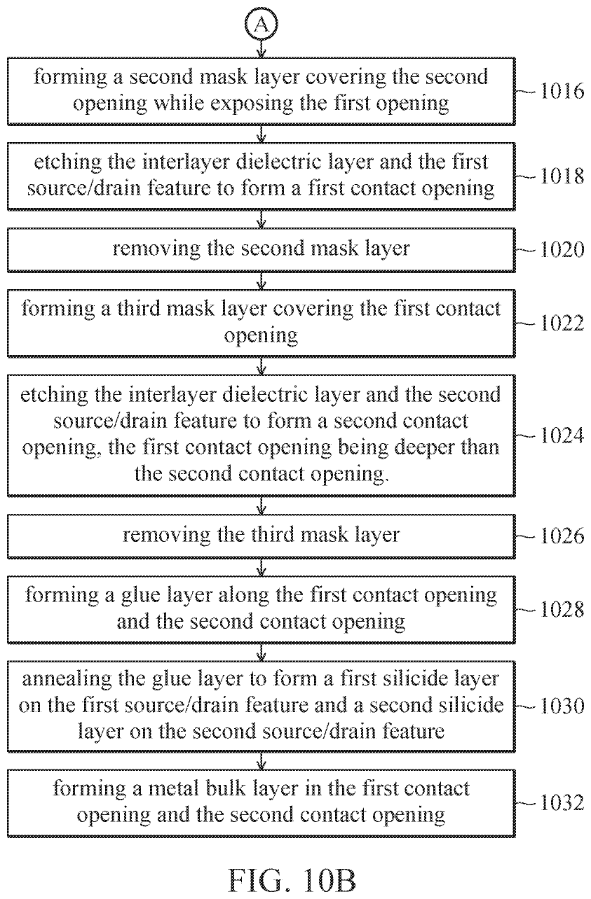

FIGS. 10A and 10B is a flowchart of a method 1000 for forming a semiconductor structure, in accordance with some embodiments of the disclosure. The method 1000 is used to form the semiconductor structure 100, 200 and/or 300 as described previously, in accordance with some embodiments.

In operation 1002, a stack including alternatingly stacked first semiconductor layers 106 and second semiconductor layers 108 over a substrate 102, in accordance with some embodiments. In operation 1004, the stack is etched to form the first fin structure 104a and a second fin structure 104b, as shown in FIG. 5A-2, in accordance with some embodiments. In operation 1006, a first source/drain feature 124a is formed over the first fin structure 104a and a second source/drain feature 124b is formed over the second fin structure 104b, as shown in FIG. 5C-2, in accordance with some embodiments. In operation 1008, an interlayer dielectric layer 134 is formed over the first source/drain feature 124a and the second source/drain feature 124b, as shown in FIG. 5C-2, in accordance with some embodiments.

In operation 1010, the first semiconductor layers 106 is removed to form a first set of nanostructures 109a and a second set of nanostructures 109b, as shown in FIG. 5D-2, in accordance with some embodiments. In operation 1012, a gate stack 140 is formed around the first set of nanostructures 109a and the second set of nanostructures 109b, as shown in FIG. 5E-2, in accordance with some embodiments.

In operation 1014, a first mask layer 158 is formed over the interlayer dielectric layer 134, as shown in FIG. 5H-2, in accordance with some embodiments. The first mask layer 158 has a first opening 160a over the first source/drain feature 124a and a second opening 160b over the second source/drain feature 124b, in accordance with some embodiments. In operation 1016, a second mask layer 162 is formed to cover the second opening 160b while exposing the first opening 160a, as shown in FIG. 5I-2, in accordance with some embodiments. In operation 1018, the interlayer dielectric layer 134 and the first source/drain feature 124a is etched to form a first contact opening 164a, as shown in FIG. 5J-2, in accordance with some embodiments. In operation 1020, the second mask layer 162 is removed, in accordance with some embodiments.

In operation 1022, a third mask layer 166 is formed to cover the first contact opening 164a, as shown in FIG. 5K-2, in accordance with some embodiments. In operation 1024, the interlayer dielectric layer 134 and the second source/drain feature 124b is etched to form a second contact opening 164b, as shown in FIG. 5L-2, in accordance with some embodiments. The first contact opening 164a is deeper than the second contact opening 164b. In operation 1026, the third mask layer 166 is removed.

In operation 1028, a glue layer 168 is formed along the first contact opening 164a and the second contact opening 164b, as shown in FIG. 5N-2, in accordance with some embodiments. In operation 1030, the glue layer 168 is annealed to form a first silicide layer 172 on the first source/drain feature 124a and a second silicide layer 172 on the second source/drain feature 124b, as shown in FIG. 5N-2, in accordance with some embodiments. In operation 1032, a metal bulk layer 174 is formed in the first contact opening 164a and the second contact opening 164b, as shown in FIG. 5N-2, in accordance with some embodiments.

As described above, the aspect of the present disclosure is directed to forming a semiconductor structure of an SRAM device including nanostructure transistors. The portion of the contact plug 178a embedded in the source/drain features 124a in the P-type well region PW1 extends to a deeper position than the position to which the portion of the contact plug 178b embedded in the source/drain features 124b in the N-type well region NW1 extends, in accordance with some embodiments. As a result, the contact area between the contact plug 178a and the source/drain feature 124a is greater than the contact area between the contact plug 178b and the source/drain feature 124b, in accordance with some embodiments. Therefore, the n-channel nanostructure transistors may have relatively strong performance while the p-channel nanostructure transistors may have relatively weak performance, which may enhance cell performance (e.g., decrease in operation voltage) and/or expand write margin metric (e.g., increase in operation speed).

Embodiments of a semiconductor structure and the method for forming the same may be provided. The semiconductor structure may include a first contact plug landing on a first source/drain feature of a first nanostructure transistor, and a second contact plug landing on a second source/drain feature of a second nanostructure transistor. The first nanostructure transistor and the second nanostructure transistor respectively may serve as a pull-down transistor and a pull-up transistor in a SRAM cell. The first contact plug may be partially embedded in the first source/drain feature, and the second contact plug may be partially embedded in the second nanostructure transistor. The bottom of the first contact plug may be located at a lower position than the bottom of the second contact plug. Therefore, performance of the SRAM cell may be enhanced and the write margin metric of the SRAM cell may expand.

In some embodiments, a semiconductor structure is provided. The semiconductor structure includes a first set of nanostructures stacked over a substrate and spaced apart from one another, a second set of nanostructures stacked over the substrate and spaced apart from one another, a first source/drain feature adjoining the first set of nanostructures, a second source/drain feature adjoining the second set of nanostructures, a first contact plug landing on and partially embedded in the first source/drain feature, and a second contact plug landing on and partially embedded in the second source/drain feature. The bottom of the first contact plug is lower than the bottom of the second contact plug.

In some embodiments, a method for forming semiconductor structure is provided. The method includes forming a first fin structure and a second fin structure over a substrate. The first fin structure includes a first set of nanostructures, and the second fin structure includes a second set of nanostructures. The method also includes forming a first source/drain feature over the first fin structure and a second source/drain feature over the second fin structure, forming an interlayer dielectric layer over the first source/drain feature and the second source/drain feature, etching the interlayer dielectric layer and the first source/drain feature to form a first contact opening in the interlayer dielectric layer and the first source/drain feature, and etching the interlayer dielectric layer and the second source/drain feature to form a second contact opening in the interlayer dielectric layer and the second source/drain feature. The first contact opening is deeper than the second contact opening.

In some embodiments, a semiconductor structure is provided. The semiconductor structure includes a pull-down transistor and a pull-up transistor. The pull-down transistor includes a first gate stack wrapping around a first set of nanostructures and a first source/drain feature. The pull-up transistor includes a second gate stack wrapping around a second set of nanostructures and a second source/drain feature. The semiconductor structure also includes an interlayer dielectric layer over the first source/drain feature and the second source/drain feature, a first contact plug in the interlayer dielectric layer and on the first source/drain feature, and a second contact plug in the interlayer dielectric layer and on the second source/drain feature. A first contact area between first contact plug and the first source/drain feature is greater than a second contact area between second contact plug and the second source/drain feature.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a first set of nanostructures stacked over a substrate and spaced apart from one another;
a second set of nanostructures stacked over the substrate and spaced apart from one another;
a first source/drain feature adjoining the first set of nanostructures;
a second source/drain feature adjoining the second set of nanostructures;
a first contact plug landing on and partially embedded in the first source/drain feature; and
a second contact plug landing on and partially embedded in the second source/drain feature, wherein a bottom of the first contact plug is lower than a bottom of the second contact plug.

2. The semiconductor structure as claimed in claim 1, wherein the first set of nanostructures includes a first nanostructure which is the uppermost one of the first set of nanostructures and a second nanostructure which is the second uppermost one of the first set of nanostructures, and the bottom of the first contact plug is located at a level between a bottom surface of the first nanostructure and a top surface of the second nano structure.

3. The semiconductor structure as claimed in claim 1, wherein the second set of nanostructures includes a third nanostructure which is the uppermost one of the second set of nanostructures, and the bottom of the second contact plug is located at a level between a top surface of the third nanostructure and a bottom surface of the third nano structure.

4. The semiconductor structure as claimed in claim 1, wherein the first set of nanostructures is located over a P-type well region, and the second set of nanostructures is located over an N-type well region.

5. The semiconductor structure as claimed in claim 1, wherein a first portion of the first contact plug embedded in the first source/drain feature has a first dimension measured from a top surface of the first source/drain feature to the bottom of the first contact plug, a second portion of the second contact plug embedded in the second source/drain feature has a second dimension measured from a top surface of the second source/drain feature to the bottom of the second contact plug, and a ratio of the second dimension to the first dimension is in a range from about 0.6 to about 0.8.

6. The semiconductor structure as claimed in claim 1, wherein the first contact plug and the second contact plug are in contact with each other.

7. The semiconductor structure as claimed in claim 1, further comprising:
a first dielectric fin structure and a second dielectric fin structure over the substrate, wherein the first source/drain feature is located between and in contact with the first dielectric fin structure and the second dielectric fin structure;
a contact etching stop layer along the first source/drain feature, the first dielectric fin structure and the second dielectric fin structure; and
an interlayer dielectric layer over the contact etching stop layer.

8. The semiconductor structure as claimed in claim 7, wherein the first contact plug partially covers an upper surface of the first dielectric fin structure.

9. The semiconductor structure as claimed in claim 1, further comprising:
a static random access memory (SRAM) cell over the substrate, comprising:
a pull-down transistor comprising a first gate stack wrapping around the first set of nanostructures and the first source/drain feature; and
a pull-up transistor comprising a second gate stack wrapping around the second set of nanostructures and the second source/drain feature.

10. A method for forming a semiconductor structure, comprising:
forming a first fin structure and a second fin structure over a substrate, wherein the first fin structure includes a first set of nanostructures, and the second fin structure includes a second set of nano structures;
forming a first source/drain feature over the first fin structure and a second source/drain feature over the second fin structure;
forming an interlayer dielectric layer over the first source/drain feature and the second source/drain feature;
etching the interlayer dielectric layer and the first source/drain feature to form a first contact opening in the interlayer dielectric layer and the first source/drain feature; and
etching the interlayer dielectric layer and the second source/drain feature to form a second contact opening in the interlayer dielectric layer and the second source/drain feature, wherein the first contact opening is deeper than the second contact opening.

11. The method for forming the semiconductor structure as claimed in claim 10, wherein the first fin structure is formed in a P-type well region, and the second fin structure is formed in an N-type well region.

12. The method for forming the semiconductor structure as claimed in claim 11, further comprising:
forming a dielectric fin structure over the substrate, wherein the dielectric fin structure overlaps a boundary between the P-type well region and the N-type well region.

13. The method for forming the semiconductor structure as claimed in claim 10, wherein the first source/drain feature is etched for a first time period, the second source/drain feature is etched for a second time period, and the first time period is longer than the second time period.

14. The method for forming the semiconductor structure as claimed in claim 10, further comprising:
forming a first mask layer over the interlayer dielectric layer, wherein the first mask layer has a first opening over the first source/drain feature and a second opening over the second source/drain feature;
forming a second mask layer covering the second opening while exposing the first opening; and
removing the second mask layer after etching the interlayer dielectric layer and the first source/drain feature and before etching the interlayer dielectric layer and the second source/drain feature.

15. The method for forming the semiconductor structure as claimed in claim 14, further comprising:
forming a third mask layer covering the first contact opening while exposing the second opening; and
removing the third mask layer after etching the interlayer dielectric layer and the second source/drain feature.

16. The method for forming the semiconductor structure as claimed in claim 10, further comprising:
forming a stack including alternatingly stacked first semiconductor layers and second semiconductor layers;
etching the stack to form the first fin structure and the second fin structure;
removing the first semiconductor layers of each of the first fin structure and the second fin structure to form the first set of nanostructures and the second set of nanostructures from the second semiconductor layers of the first fin structure and the second fin structure, respectively; and
forming a gate stack wrapping around the first set of nanostructures and the second set of nanostructures.

17. The method for forming the semiconductor structure as claimed in claim 10, further comprising:
forming a glue layer along the first contact opening and the second contact opening; and
annealing the glue layer such that a first portion of the glue layer is formed into a first silicide layer on the first source/drain feature and a second portion of the glue layer is formed into a second silicide layer on the second source/drain feature, wherein a contact area between the first silicide layer and the first source/drain feature is greater than a contact area between the second silicide layer and the second source/drain feature.

18. A semiconductor structure, comprising:
a pull-down transistor comprising a first gate stack wrapping around a first set of nanostructures and a first source/drain feature; and
a pull-up transistor comprising a second gate stack wrapping around a second set of nanostructures and a second source/drain feature;
an interlayer dielectric layer over the first source/drain feature and the second source/drain feature;
a first contact plug in the interlayer dielectric layer and on the first source/drain feature; and
a second contact plug in the interlayer dielectric layer and on the second source/drain feature, wherein a first contact area between first contact plug and the first source/drain feature is greater than a second contact area between second contact plug and the second source/drain feature.

19. The semiconductor structure as claimed in claim 18, wherein the first set of nanostructures is formed in a p-type well region, and the second set of second set of nanostructures is formed in an n-type well region.

20. The semiconductor structure as claimed in claim 18, wherein the pull-down transistor further comprises a third source/drain feature, the pull-up transistor further comprises a fourth source/drain feature, and the semiconductor structure further comprises:
a third contact in the interlayer dielectric layer and on the third source/drain feature and the fourth source/drain feature, wherein the third contact has a first bottom surface in contact with the third source/drain feature and a second bottom surface in contract with the fourth source/drain feature, the first bottom surface of the third contact is lower than the second bottom surface of the third contact.
